(19) United States
(12) Patent Application Publication
(10) Pub. No.: US 2026/0056297 A1
(43) Pub. Date: Feb. 26, 2026

(54) LIGHT RECEIVING ELEMENT AND DISTANCE MEASURING DEVICE

(71) Applicant: Sony Semiconductor Solutions Corporation, Kanagawa (JP)

(72) Inventor: Takahiro HAMASAKI, Kanagawa (JP)

(73) Assignee: Sony Semiconductor Solutions Corporation, Kanagawa (JP)

(21) Appl. No.: 19/105,739

(22) PCT Filed: Aug. 21, 2023
(86) PCT No.: PCT/JP2023/029949

§ 371 Date: Feb. 21, 2025

(30) Foreign Application Priority Data
Aug. 29, 2022 (JP) 2022-136277

(51) Int. Cl. G01S 7/481; H10F 30/22; H10F 77/00; H10F 77/40

(52) U.S. Cl. CPC G01S 7/4816; H10F 30/22; H10F 77/413; H10F 77/957

(57) ABSTRACT

A light receiving element includes a plurality of pixels, each pixel includes a photoelectric conversion unit that generates carriers according to an amount of received light; a first conductor portion is disposed inside a first insulator that provides insulation between adjacent pixels; a second conductor portion is disposed on an outer edge side of a light receiving region of the photoelectric conversion unit and has an opening region; and a charge accumulation region corresponds to the opening region and is disposed further on an outer edge side than the second conductor portion.

### TECHNICAL FIELD

The present disclosure relates to a light receiving element and a distance measuring device.

### BACKGROUND ART

As a distance measurement method in a distance measuring device, for example, the indirect time of flight (Indirect ToF) method is commonly known. In this Indirect ToF method, the time between when pattern light is emitted to a target object and when the pattern light is received as reflected light is generated as a phase difference, and a distance measurement value is generated based on this phase difference.

### CITATION LIST

### Patent Literature

### [PTL 1]

Japanese Patent Application No. 2015-561233

### SUMMARY

### Technical Problem

It is known that a distance measurement error in a distance measuring device is determined by the main drive frequency and the electric charge distribution efficiency. However, when the main drive frequency is increased to reduce the distance measurement error, there is a risk that the electric charge distribution efficiency will decrease.

Therefore, the present disclosure provides a light receiving element and a distance measuring device that can suppress a decrease in the electric charge distribution efficiency even when the main drive frequency is increased.

### Solution to Problem

In order to solve the problem, the present disclosure provides a light receiving element including a plurality of pixels, each pixel including
a photoelectric conversion unit that generates carriers according to an amount of received light;
a first conductor portion that is disposed inside a first insulator that provides insulation between adjacent pixels;
a second conductor portion that is disposed on an outer edge side of a light receiving region of the photoelectric conversion unit and has an opening region; and
a charge accumulation region that corresponds to the opening region and is disposed further on an outer edge side than the second conductor portion.

The photoelectric conversion unit may be made of a semiconductor of a first conductivity type, and
the charge accumulation region may be disposed on one surface side of the photoelectric conversion unit, and may have a higher impurity density than the photoelectric conversion unit.

The second conductor portion may be disposed inside a second insulator that provides insulation from the photoelectric conversion unit.

The second conductor portion may include first, second, third, and fourth conductors that are spaced apart from one another.

The first, second, third, and fourth conductors may be arranged to surround the light receiving region of the photoelectric conversion unit.

The first, second, third, and fourth conductors may each be arranged in any one of a quadrangular shape, a circular shape, and an octagonal shape.

The second insulator may be disposed for each of the first, second, third, and fourth conductors so that resulting second insulators are spaced apart from one another.

Each of the first, second, third, and fourth conductors may be made up of two conductors spaced apart from each other.

Each of the first, second, third, and fourth conductors may be made up of two conductors spaced apart from each other, and second insulators in which the two spaced-apart conductors are arranged in each second insulator may be arranged spaced apart from each other.

The first conductor portion and the second conductor portion may run from one surface side to the other surface side of the photoelectric conversion unit.

The charge accumulation region may include first, second, third, and fourth charge accumulation regions that are arranged spaced apart from one another. The charge accumulation region may include first to eighth charge accumulation regions that are spaced apart from one another, and the first to eighth charge accumulation regions may be arranged corresponding to eight opening regions of the second conductor portion, respectively.

A central conductor portion may be further included, in a center of the photoelectric conversion unit, that is surrounded by an insulator that provides insulation from the photoelectric conversion unit, and a predetermined electric potential may be applied to the central conductor portion.

An on-chip lens may be disposed on the other surface side of the photoelectric conversion unit.

An impurity layer of a second conductivity type different from the first conductivity type may be disposed in a surface layer of the photoelectric conversion unit.

The impurity layer may have a fixed electric potential.

The first conductor portion may include conductors that are spaced apart from one another corresponding to the first, second, third, and fourth charge accumulation regions, and are applied with a predetermined electric potential, first, second, third, and fourth periodic signals whose electric potential changes periodically may be applied to the first, second, third, and fourth conductors, respectively, and phases of the first, second, third, and fourth periodic signals may differ from one another by 90 degrees.

The first conductor portion may include conductors that are spaced apart from one another corresponding to the first to eighth charge accumulation regions, and are applied with a predetermined electric potential, and
first to eighth periodic signals whose electric potential changes periodically may be applied to the eight spaced-apart conductors, respectively, and phases of the first to eighth periodic signals may differ from one another by 45 degrees.

The first to eighth charge accumulation regions may have pairs of charge accumulation regions with respect to the center of the photoelectric conversion unit,
the first conductor portion may include conductors that are spaced apart from one another corresponding to the first to eighth charge accumulation regions, and are applied with a predetermined electric potential,
four groups, each being made up of four conductors that form two openings corresponding to the pair of charge accumulation regions, may be made,
first to fourth periodic signals whose electric potential changes periodically may be applied to the four conductors in each of the four groups, and phases of the first to fourth periodic signals may differ from one another by 90 degrees.

A substrate that is disposed on one surface side of the photoelectric conversion unit may be further included,
the first, second, third, and fourth charge accumulation regions may be arranged on the substrate,
the first conductor portion may include first, second, third, and fourth first conductors that are separated apart from one another corresponding to the first, second, third, and fourth charge accumulation regions, and
each of the first, second, third, and fourth charge accumulation regions may be connected to a corresponding one of the first, second, third, and fourth first conductors via a gate transistor.

A substrate disposed on one surface side of the photoelectric conversion unit may be further included,
the first, second, third, and fourth charge accumulation regions may be arranged on the substrate,
the first conductor portion may include first, second, third, and fourth first conductors that are separated apart from one another corresponding to the first, second, third, and fourth charge accumulation regions,
a first, second, third, and fourth embedded memories adjacent to the first, second, third, and fourth first conductors, respectively, may be further included, and
each of the first, second, third, and fourth charge accumulation regions may be connected to a corresponding one of the first, second, third, and fourth embedded memories via a gate transistor.

The first insulator and the second insulator may be integrally formed to electrically isolate the first, second, third, and fourth embedded memories.

A substrate disposed on one surface side of the photoelectric conversion unit, and a memory electrically connectable to the first, second, third, and fourth charge accumulation regions may be further included, and
the memory may be formed in the substrate.

The memory may be formed of meteal oxide semiconductor (MOS) or meteal-insulator-metal (MIM).

The first conductor portion may be shared between adjacent pixels.

The first conductor portion may include conductors that are spaced apart from one another corresponding to the first, second, third, and fourth charge accumulation regions, and
a light-shielding portion may be further included that covers one side or the other side of the spaced-apart first conductor portion.

The first, second, third, and fourth conductors may be made of a metal material having a predetermined reflectivity.

Circuits configured corresponding to the first, second, third, and fourth charge accumulation regions may be arranged in the photoelectric conversion unit.

A light receiving element, and
a signal processing unit that generates a distance measurement value to a target object using a measurement signal based on the light receiving element may be further included.

### BRIEF DESCRIPTION OF DRAWINGS

FIG. 1 is a diagram illustrating a schematic configuration example of a distance measuring system to which the present technology is applied.

FIG. 2 is a block diagram illustrating a configuration example of a distance measuring device.

FIG. 3 is a diagram schematically illustrating a relationship between a distance to a target object and a distance measurement method.

FIG. 4 is a block diagram illustrating a configuration example of a light receiving element.

FIG. 5 is a plan view illustrating a configuration example of a pixel.

FIG. 6 is a cross-sectional view taken along BB of FIG. 5.

FIG. 7 is a cross-sectional view taken along DD of FIG. 5.

FIG. 8 is a diagram schematically illustrating an electric potential when no electric charge is transferred.

FIG. 9 is a diagram schematically illustrating an electric potential when electric charges are transferred.

FIG. 10 is another diagram schematically illustrating an electric potential when electric charges are transferred.

FIG. 11 is a diagram schematically illustrating electric charge transfer in a comparative example.

FIG. 12 schematically illustrates a timing chart of electric charge generation as the comparative example.

FIG. 13 is a diagram illustrating a circuit configuration example of the pixel.

FIG. 14 is a diagram illustrating a configuration example of a pixel circuit.

FIG. 15 is a diagram illustrating a configuration example of a pixel circuit.

FIG. 16 is a diagram illustrating a configuration example of a pixel circuit.

FIG. 17 illustrates an example of control signals supplied from a row scanning circuit.

FIG. 18 is a diagram schematically illustrating the number of electric charges.

FIG. 19 illustrates a relationship between a light emission pattern of a light emitting source and detection signals at the pixel.

FIG. 20 is a diagram illustrating a cross section of the pixel.

FIG. 21 is a diagram illustrating a configuration example of a pixel according to a second embodiment.

FIG. 22 is a diagram illustrating a configuration example of a pixel according to Modification Example 1 of the second embodiment.

FIG. 23 is a plan view illustrating a configuration of a pixel according to a third embodiment.

FIG. 24 is a plan view illustrating a configuration of a pixel according to a fourth embodiment.

FIG. 25 is a plan view illustrating a configuration of a pixel according to Modification Example 1 of the fourth embodiment.

FIG. 26 is a plan view illustrating a configuration of a pixel according to a fifth embodiment.

FIG. 27 is a plan view illustrating a configuration of a pixel according to Modification Example 1 of the fifth embodiment.

FIG. 28 is a diagram illustrating a configuration example of a pixel according to a sixth embodiment.

FIG. 29 is a diagram illustrating an equivalent circuit example of the pixel according to the sixth embodiment.

FIG. 30 is a diagram illustrating a configuration example of a pixel according to Modification Example 1 of the sixth embodiment.

FIG. 31 is a diagram illustrating an equivalent circuit example of the pixel according to Modification Example 1 of the sixth embodiment.

FIG. 32 is a diagram illustrating a configuration example of a pixel according to Modification Example 2 of the sixth embodiment.

FIG. 33 is a cross-sectional view of a pixel 1 according to Modification Example 1 of the second embodiment.

FIG. 34 is a diagram illustrating an equivalent circuit example of a pixel according to a seventh embodiment.

FIG. 35 is a plan view illustrating a configuration example of a pixel according to an eighth embodiment.

FIG. 36 is a plan view illustrating a configuration example of a pixel according to Modification Example 1 of the eighth embodiment.

FIG. 37 is a plan view illustrating a configuration example of the pixel according to the eighth embodiment.

FIG. 38 is a cross-sectional view taken along AA illustrating a configuration example of a pixel according to a tenth embodiment.

FIG. 39 is a cross-sectional view taken along AA illustrating a configuration example of a pixel according to an eleventh embodiment.

FIG. 40 is a diagram illustrating a configuration example of a pixel according to a twelfth embodiment.

FIG. 41 is a plan view illustrating a configuration example of a pixel according to a thirteenth embodiment.

### DESCRIPTION OF EMBODIMENTS

Embodiments of a light receiving element and a distance measuring device will be described below with reference to the drawings. The following description will focus on the main components of the light receiving element and the distance measuring device. The light receiving element and the distance measuring device may include components and functions that are not illustrated or described. The following description does not exclude components or functions that are not illustrated or described.

### First Embodiment

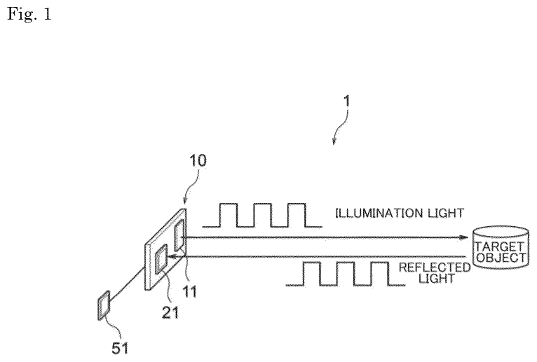

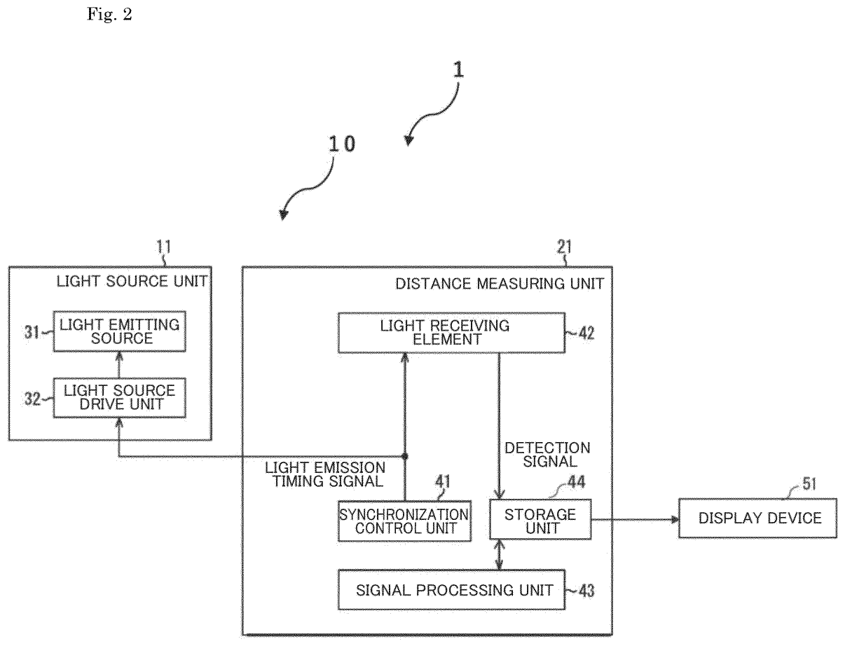

FIG. 1 is a diagram illustrating a schematic configuration example of a distance measuring system to which the present technology is applied. The distance measuring system 1 illustrated in FIG. 1 includes a distance measuring device 10 and a display device 51 (see FIG. 2). The distance measuring device 10 also includes a light source unit 11 and a distance measuring unit 21. The light source unit 11 generates illumination light while modulating the light at a timing according to a light emission timing signal, and illuminates a target object with the illumination light via an illumination optical system. The illumination light emitted from the light source unit 11 is reflected by the target object, and enters the distance measuring unit 21 via a light receiving optical system.

The distance measuring unit 21 receives the reflected light that is reflected by and comes from the target object. The distance measuring unit 21 generates a detection signal according to the amount of reflected light received. Based on the detection signal, the distance measuring unit 21 calculates and outputs a distance measurement value, which is a measurement value of the distance to the predetermined target object.

FIG. 2 is a block diagram illustrating a configuration example of the distance measuring device 10. As illustrated in FIG. 2, the light source unit 11 of the distance measuring device 10 includes a light emitting source 31 and a light source drive unit 32. The distance measuring unit 21 of the distance measuring device 10 includes a synchronization control unit 41, a light receiving element 42, a signal processing unit 43, and a storage unit 44.

The light emitting source 31 is composed of a light source array in which a plurality of light emitting elements, such as vertical cavity surface emitting lasers (VCSELs), are arranged in a planar direction. The light emitting source 31 emits light while modulating the light at a timing according to the light emission timing signal supplied from the synchronization control unit 41 of the distance measuring unit 21 under the control of the light source drive unit 32, to illuminate a predetermined target object with the resulting illumination light. The illumination light is, for example, infrared light having a wavelength in the range of about 850 nm to 940 nm.

The light source drive unit 32 is composed of, for example, a laser driver, and causes each light emitting element of the light emitting source 31 to emit light in response to the light emission timing signal supplied from the synchronization control unit 41. The synchronization control unit 41 of the distance measuring unit 21 generates the light emission timing signal for controlling the timing at which each light emitting element of the light emitting source 31 emits light, and supplies the generated light emission timing signal to the light source drive unit 32. The synchronization control unit 41 also supplies the light emission timing signal to the light receiving element 42 in order to drive the light receiving element 42 in synchronization with the timing of light emission of the light emitting source 31. For example, the light emission timing signal can be a rectangular wave signal (pulse signal) that indicates on and off at a predetermined frequency (e.g., 10 MHz, 20 MHz, 50 MHz, 120 MHz, etc.). The light emission timing signal is not limited to a rectangular wave as long as it is a periodic signal, and may be, for example, a sine wave.

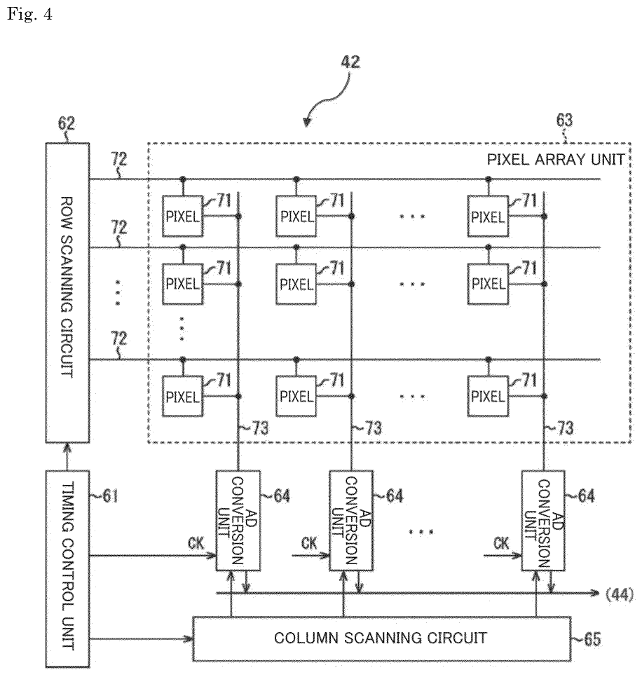

The light receiving element 42 receives reflected light, which is reflected by the target object, by means of a pixel array unit 63 (see FIG. 4) in which a plurality of pixels 71 (see FIG. 4) are two-dimensionally arranged in a matrix. The light receiving element 42 then supplies a detection signal corresponding to the amount of reflected light received to the signal processing unit 43 for each pixel of the pixel array unit 63. The light receiving element 42 is formed of, for example, a semiconductor element.

The signal processing unit 43 is configured to include, for example, a central processing unit (CPU). The signal processing unit 43 performs signal processing according to a program stored in the storage unit 44. Specifically, the signal processing unit 43 generates a distance measurement value, which indicates the distance from the light receiving element 42 to the predetermined target object, based on the detection signal supplied from the light receiving element 42. The distance measurement method according to the present embodiment is, for example, a time of flight (ToF) method, which detects the time from when the illumination light is emitted to when the reflected light is received as a phase difference, and calculates the distance based on the phase difference.

The storage unit 44 is implemented by, for example, a semiconductor memory element such as random access memory (RAM) and flash memory, a hard disk, or an optical disk. The storage unit 44 stores the detection signal, the distance measurement value, and others. The display device 51 is, for example, a monitor. The display device 51 is capable of displaying, for example, a two-dimensional distance image.

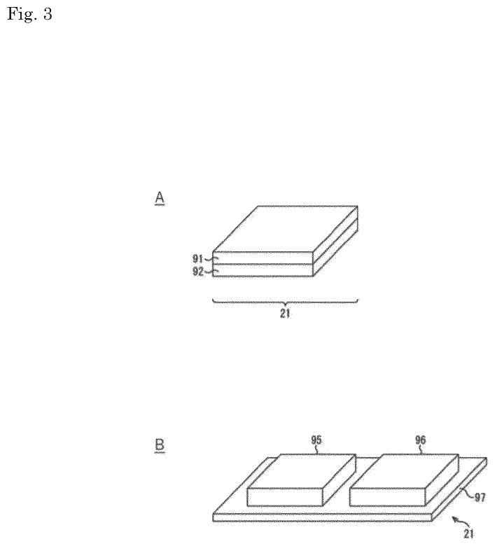

FIG. 3 is a perspective view illustrating a chip configuration example of the distance measuring unit 21. The distance measuring unit 21 can be configured as one chip in which a first die (substrate) 91 and a second die (substrate) 92 are stacked, as illustrated in A of FIG. 4. The first die 91 includes, for example, the synchronization control unit 41 and the light receiving element 42, and the second die 92 includes, for example, the signal processing unit 43 and the storage unit 44.

The distance measuring unit 21 may be configured in three layers in which another logic die is stacked in addition to the first die 91 and the second die 92, or may be configured in four or more layers of dies (substrates). The distance measuring unit 21 can be configured, for example, as illustrated in B of FIG. 4, in which a first chip 95 serving as the light receiving element 42 and a second chip 96 serving as the signal processing unit 43 are formed on an intermediate substrate 97. The synchronization control unit 41 is configured to be included in either the first chip 95 or the second chip 96.

FIG. 4 is a block diagram illustrating a configuration example of the light receiving element 42. The light receiving element 42 includes a timing control unit 61, a row scanning circuit 62, the pixel array unit 63, a plurality of analog-to-digital (AD) conversion units 64, a column scanning circuit 65, and the signal processing unit 43. In the pixel array unit 63, a plurality of pixels 71 are two-dimensionally arranged in a matrix in the row and column directions. As used herein, the row direction refers to a direction in which the pixels 71 are arranged in the horizontal direction, and the column direction refers to a direction in which the pixels 71 are arranged in the vertical direction. The row direction is a transverse direction in the drawing, and the column direction is a longitudinal direction in the drawing.

The timing control unit 61 is composed of, for example, a timing generator that generates various timing signals, and generates various timing signals in synchronization with the light emission timing signal supplied from the synchronization control unit 41 (FIG. 2), and supplies the generated signals to the row scanning circuit 62, the AD conversion units 64, and the column scanning circuit 65. In other words, the timing control unit 61 controls the drive timings of the row scanning circuit 62, the AD conversion unit 64, and the column scanning circuit 65.

The row scanning circuit 62 is configured by, for example, a shift register, an address decoder, or the like, to drive all pixels 71 of the pixel array unit 63 at the same time, row by row, or the like. The pixel 71 receives reflected light under the control of the row scanning circuit 62, and outputs a detection signal (pixel signal) having a level corresponding to the amount of light received. Details of the pixel 71 will be described later.

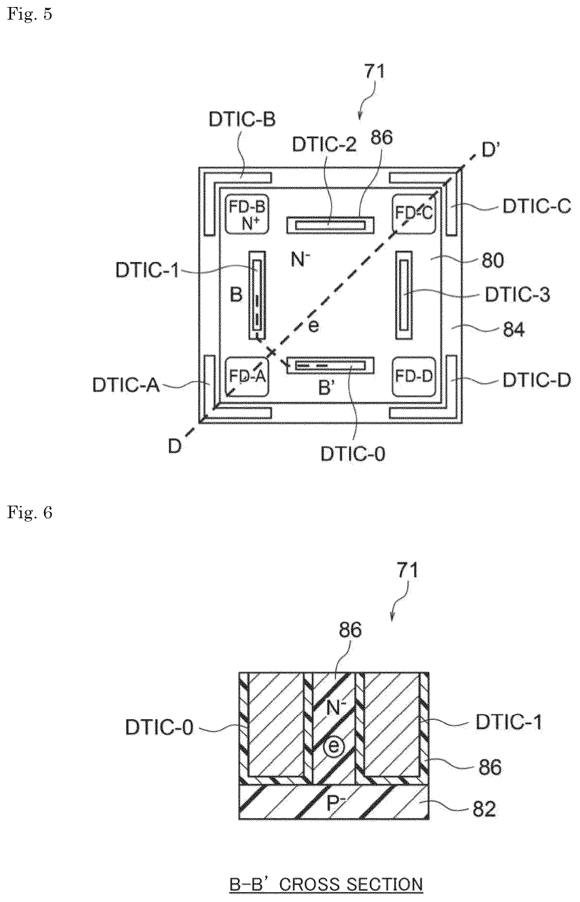

For the matrix arrangement of pixels of the pixel array unit 63, pixel drive lines 72 are wired in the horizontal direction for each pixel row, and vertical signal lines 73 are wired in the vertical direction for each pixel column. The pixel drive line 72 transmits a drive signal for driving to read out a detection signal from the corresponding pixel 71. In the following description, the coordinates of a pixel 71 are sometimes expressed as (x, y). x is the row position of a pixel I, and y is the column position. In FIG. 5, the pixel drive line 72 is illustrated as a single wire, but in reality it is made up of a plurality of wires. Similarly, the vertical signal line 73 is illustrated as a single wire, but in reality it is made up of a plurality of wires.

The AD conversion unit 64 is provided for each column, and performs AD conversion of a detection signal supplied from the corresponding pixel 71 in the corresponding column via the vertical signal line 73 in synchronization with a clock signal CK supplied from the timing control unit 61. The AD conversion unit 64 outputs the AD-converted detection signal (detection data) to the signal processing unit 43 under the control of the column scanning circuit 65. The column scanning circuit 65 sequentially selects the AD conversion units 64 and causes the selected one to output the detection data after AD conversion to the signal processing unit 43.

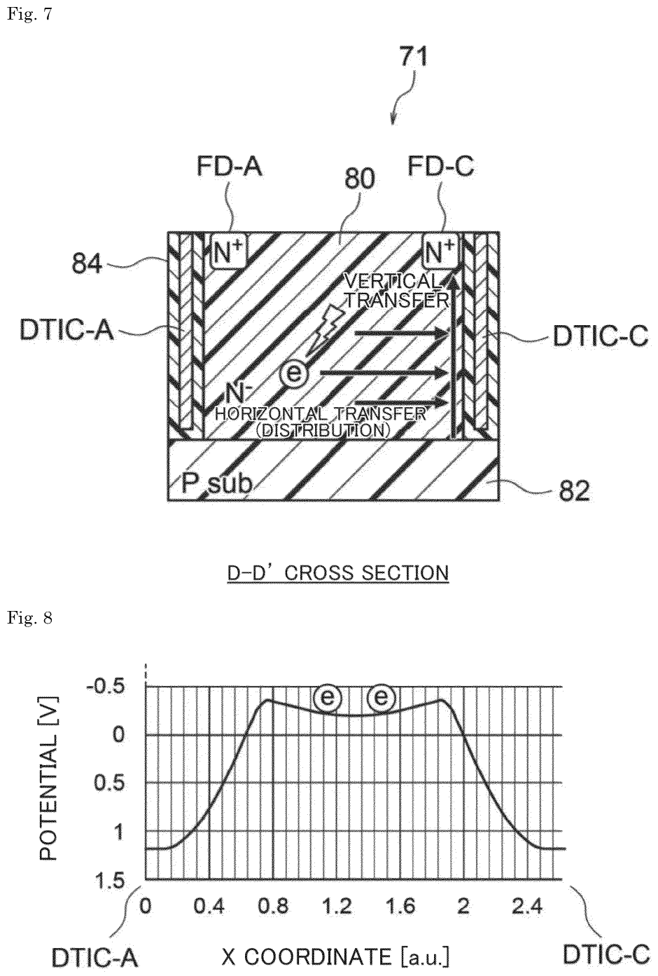

A configuration example of the pixel 71 will now be described with reference to FIGS. 5 to 7. FIG. 5 is a plan view illustrating the configuration example of the pixel 71. FIG. 6 is a cross-sectional view taken along BB of FIG. 5. FIG. 7 is a cross-sectional view taken along DD of FIG. 5.

As illustrated in FIGS. 5 to 7, the pixel 71 includes a photoelectric conversion unit 80, a substrate 82, a first insulator 84, second insulators 86, a first conductor DTIC-A, a second conductor DTIC-B, a third conductor DTIC-C, a fourth conductor DTIC-D, a fifth conductor DTIC-0, a sixth conductor DTIC-1, a seventh conductor DTIC-2, and an eighth conductor DTIC-3. The conductor DTIC (DTIC: DTI-filled with Conductor) refers to a trench portion (DTI: Deep Trench Isolation) physically provided in a semiconductor substrate, for example, in which at least a portion of the conductor is contained. The conductor may be fully embedded in the semiconductor substrate, or may be provided without reaching the surface of the semiconductor substrate. A void (cavity) may be included in the conductor. The conductor may be provided so that a part of the conductor protrudes from the surface of the semiconductor substrate.

The photoelectric conversion unit 80 is an N-semiconductor region, which is a first conductivity type region. The substrate 82 is configured as a P-semiconductor region, which is a second conductivity type region, below the photoelectric conversion unit 80. For example, reflected light is collected in a light receiving region surrounded by the fifth conductor DTIC-0, the sixth conductor DTIC-1, the seventh conductor DTIC-2, and the eighth conductor DTIC-3 of the photoelectric conversion unit 80. Accordingly, the photoelectric conversion unit 80 generates electric charges proportional to the amount of reflected light received that is collected in the light receiving region, for example. The description of the embodiment gives a case where the first conductivity type is N-type and the second conductivity type is P-type by way of example. However, the conductivity types are not limited to the case. For example, the conductivity types may be selected in reverse, with the first conductivity type being P-type and the second conductivity type being N-type.

The first insulator 84 is formed in a quadrangular shape on the outer periphery of the pixel 71. The first insulator 84 is configured as a partition wall that runs from the upper surface portion of the photoelectric conversion unit 80 to the substrate 82, and insulates adjacent pixels.

As illustrated in FIGS. 5 and 7, an L-shaped trench is formed at each corner of the first insulator 84, running from the upper surface of the photoelectric conversion unit 80 to the upper surface of the substrate 82. The first conductor DTIC-A, the second conductor DTIC-B, the third conductor DTIC-C, and the fourth conductor DTIC-D are formed within these L-shaped trenches, respectively.

As illustrated in FIGS. 5 and 6, the second insulators 86 are arranged, for example, at equal distances from the center position of the photoelectric conversion unit 80 and parallel to each side of the quadrangular first insulator 84, spaced apart from one another. Each second insulator 86 is formed, for example, running from the upper surface of the photoelectric conversion unit 80 to the upper surface of the substrate 82.

An I-shaped trench is formed in each of the second insulators 86 spaced apart from one another. The fifth conductor DTIC-0, the sixth conductor DTIC-1, the seventh conductor DTIC-2, and the eighth conductor DTIC-3 are formed within these I-shaped trenches, respectively.

As illustrated in FIGS. 5 and 7, a first charge accumulation region FD-A, a second charge accumulation region FD-B, a third charge accumulation region FD-C, and a fourth charge accumulation region FD-D are provided at four symmetrical positions with a space between them with respect to the center position of the light receiving region of the photoelectric conversion unit 80 so as to surround the light receiving region. The first charge accumulation region FD-A, the second charge accumulation region FD-B, the third charge accumulation region FD-C, and the fourth charge accumulation region FD-D are each configured as an N+ type having a higher concentration of donor impurities than the photoelectric conversion unit 80.

Thus, the pixel 71 includes the photoelectric conversion unit 80, which is an N-semiconductor region, and the first charge accumulation region FD-A, the second charge accumulation region FD-B, the third charge accumulation region FD-C, and the fourth charge accumulation region FD-D, which are N+ semiconductor regions having a higher concentration of donor impurities than the photoelectric conversion unit 80. As used herein, examples of donor impurities include elements belonging to Group 5 in the periodic table of elements such as phosphorus (P) or arsenic (As) for Si, and examples of acceptor impurities include elements belonging to Group 3 in the periodic table of elements such as boron (B) for Si. An element that serves as a donor impurity is sometimes referred to as a donor element, and an element that serves as an acceptor impurity is sometimes referred to as an acceptor element.

As illustrated in FIG. 5 again, when the pixel 71 is driven, for example, a voltage of +0.5 volts is applied to the first conductor DTIC-A, the second conductor DTIC-B, the third conductor DTIC-C, and the fourth conductor DTIC-D via the pixel drive line 72 (see FIG. 4). In addition, a voltage signal synchronized with a control signal Scdti0 (see FIG. 17 described later) is supplied to the fifth conductor DTIC-0 from the row scanning circuit 62 via the pixel drive line 72. Similarly, a voltage signal synchronized with a control signal Scdti1 (see FIG. 17 described later) is supplied to the sixth conductor DTIC-1 from the row scanning circuit 62 via the pixel drive line 72. Similarly, a voltage signal synchronized with a control signal Scdti2 (see FIG. 17 described later) is supplied to the seventh conductor DTIC-2 (see FIG. 17 described later) from the row scanning circuit 62 via the pixel drive line 72. Similarly, a voltage signal synchronized with a control signal Scdti3 (see FIG. 17 described later) is supplied to the eighth conductor DTIC-3 from the row scanning circuit 62 via the pixel drive line 72.

When the control signals Scdti0 to Scdti4 are at high level, a voltage of, for example, −0.6 volts (ON state) is applied to the corresponding fifth conductor DTIC-0, sixth conductor DTIC-1, seventh conductor DTIC-2, and eighth conductor DTIC-3. On the other hand, when the control signals Scdti0 to Scdti4 are at low level, a voltage of, for example, −2.2 volts (OFF state) is applied to the corresponding fifth conductor DTIC-0, sixth conductor DTIC-1, seventh conductor DTIC-2, and eighth conductor DTIC-3.

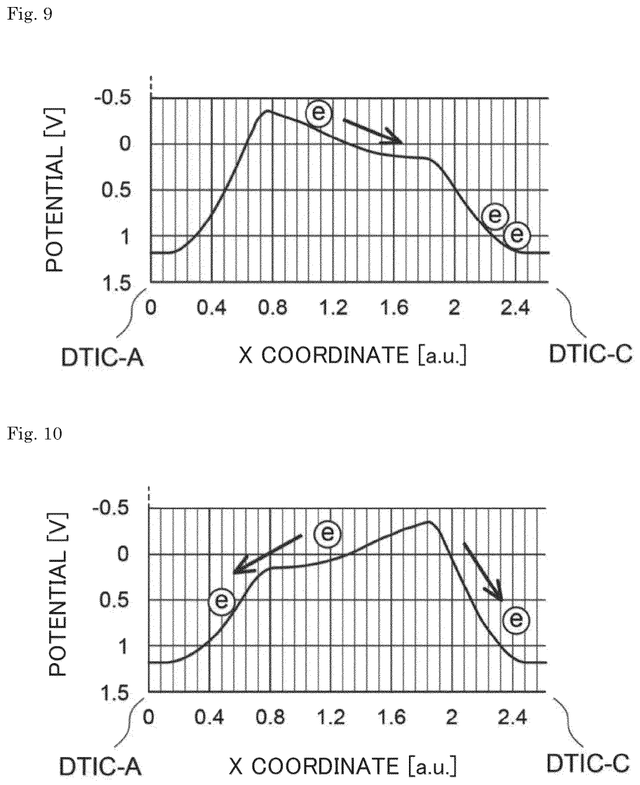

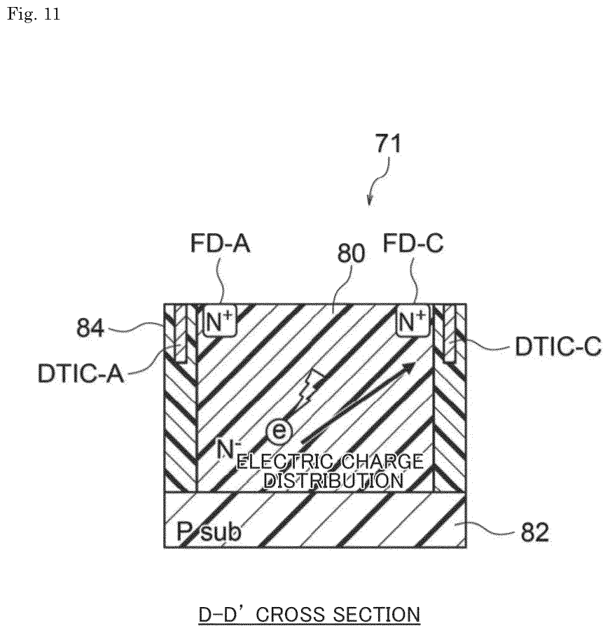

FIG. 8 is a diagram illustrating an electric potential when no electric charge is transferred along the cross-sectional view taken along DD of FIG. 5. The vertical axis indicates the electric potential, and the horizontal axis indicates the position along the DD cross-sectional view. FIG. 9 illustrates states in which, for example, a voltage of +0.5 volts is applied to the first conductor DTIC-A, the second conductor DTIC-B, the third conductor DTIC-C, and the fourth conductor DTIC-D, and a voltage of −2.2 volts (OFF state) is applied to the fifth conductor DTIC-0, the sixth conductor DTIC-1, the seventh conductor DTIC-2, and the eighth conductor DTIC-3. In this case, the voltage of −2.2 volts applied to the fifth conductor DTIC-0, the sixth conductor DTIC-1, the seventh conductor DTIC-2, and the eighth conductor DTIC-3 prevents the electric charges generated in proportion to the light received by the photoelectric conversion unit 80 from escaping outside the light receiving region surrounded by the fifth conductor DTIC-0, the sixth conductor DTIC-1, the seventh conductor DTIC-2, and the eighth conductor DTIC-3.

FIG. 9 is a diagram illustrating an electric potential when electric charges are transferred along the cross-sectional view taken along DD of FIG. 5. The vertical axis indicates the electric potential, and the horizontal axis indicates the position along the cross-sectional view taken along DD. In FIG. 9, a voltage of −0.6 volts (ON state) is applied to the seventh conductor DTIC-2 (see FIG. 5) and the eighth conductor DTIC-3, a voltage of −2.2 volts (OFF state) is applied to the fifth conductor DTIC-0 and the sixth conductor DTIC-1, and a voltage of 0.5 volts is applied to the first conductor DTIC-A, the second conductor DTIC-B, the third conductor DTIC-C, and the fourth conductor DTIC-D. In this case, an electric potential gradient is generated in the electric potential, and electric charges are horizontally transferred to the third charge accumulation region FD-C side through an opening formed by the seventh conductor DTIC-2 and the eighth conductor DTIC-3.

Again, as illustrated in FIGS. 6 and 7, the first conductor DTIC-A, the second conductor DTIC-B, the third conductor DTIC-C, the fourth conductor DTIC-D, the fifth conductor DTIC-0, the sixth conductor DTIC-1, the seventh conductor DTIC-2, and the eighth conductor DTIC-3 are formed running from the upper surface to the lower surface of the photoelectric conversion unit 80. Therefore, for example, when electric charges are transferred to the third charge accumulation region FD-C side, the electric charges generated in the photoelectric conversion unit 80 reach the third conductor DTIC-C in the horizontal direction over the shortest distance. Specifically, as illustrated in FIG. 9, an electric potential gradient is generated in the horizontal direction, and electric charges are horizontally transferred to the third charge accumulation region FD-C over the shortest distance through the opening formed by the seventh conductor DTIC-2 and the eighth conductor DTIC-3. Then, they are vertically transferred.

FIG. 10 is a diagram illustrating an electric potential when electric charges are transferred to the first charge accumulation region FD-A side along the cross-sectional view taken along DD of FIG. 5. The vertical axis indicates the electric potential, and the horizontal axis indicates the position along the cross-sectional view taken along DD. In FIG. 10, a voltage of −2.2 volts (OFF state) is applied to the seventh conductor DTIC-2 (see FIG. 5) and the eighth conductor DTIC-3, a voltage of −0.6 volts (ON state) is applied to the fifth conductor DTIC-0 and the sixth conductor DTIC-1, and a voltage of 0.5 volts is applied to the first conductor DTIC-A, the second conductor DTIC-B, the third conductor DTIC-C, and the fourth conductor DTIC-D.

It is now assumed that the electric charge transfer direction changes from the third charge accumulation region FD-D side to the first charge accumulation region FD-A side. In other words, it is when the electric potential illustrated in FIG. 9 is switched to the electric potential illustrated in FIG. 10. Even in this case, a voltage of −2.2 volts (OFF state) is still applied to the seventh conductor DTIC-2 (see FIG. 5) and the eighth conductor DTIC-3, so that the electric potential has a shape having an electric potential gradient on the right side of FIG. 10. Therefore, the electric charges that have passed through the seventh conductor DTIC-2 (see FIG. 5) and the eighth conductor DTIC-3 are vertically transferred to the third charge accumulation region FD-C without moving to the first charge accumulation region FD-A side.

Similarly, an electric potential when electric charges are transferred to the second charge accumulation region FD-B is generated by applying a voltage of −2.2 volts (OFF state) to the fifth conductor DTIC-0 (see FIG. 5) and the eighth conductor DTIC-3, a voltage of −0.6 volts (ON state) to the sixth conductor DTIC-1 and the seventh conductor DTIC-2, and a voltage of 0.5 volts to the first and the fourth conductor DTIC-D.

Similarly, an electric potential when electric charges are transferred to the second charge accumulation region FD-D is generated by applying a voltage of −2.2 volts (OFF state) to the sixth conductor DTIC1 (see FIG. 5) and the seventh conductor DTIC-2, a voltage of −0.6 volts (ON state) to the fifth conductor DTIC-0 and the eighth conductor DTIC-3, and a voltage of 0.5 volts to the first conductor DTIC-A, the second conductor DTIC-B, the third conductor DTIC-C, and the fourth conductor DTIC-D.

FIG. 11 is a diagram schematically illustrating the movement of electric charge when, as a comparative example, the lengths of the first conductor DTIC-A, the second conductor DTIC-B, the third conductor DTIC-C, the fourth conductor DTIC-D, the fifth conductor DTIC-0, the sixth conductor DTIC-1, the seventh conductor DTIC-2, and the eighth conductor DTIC-3 are each set to, for example, about a quarter of their original length. In such a case, the electric charge moves obliquely, which takes time to be transferred. In addition, if the electric charge transfer direction changes from the third charge accumulation region FD-D side to the first charge accumulation region FD-A side, the electric charge in the region where the electric potential is not formed in the horizontal direction will move back to the first charge accumulation region FD-A side and be accumulated there.

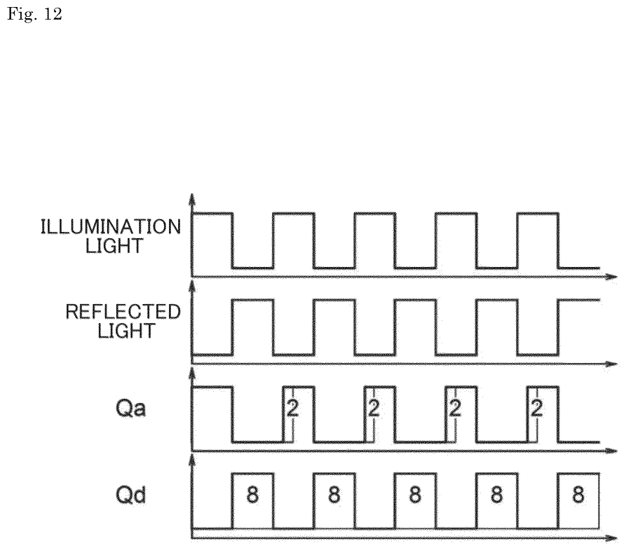

FIG. 12 schematically illustrates a timing chart of electric charge generation as the comparative example. From the top, illumination light, reflected light, an electric charge transfer timing Qa to the first charge accumulation region FD-A, and an electric charge transfer timing Qd to the third charge accumulation region FD-C are indicated. The high level for the illumination light and the reflected light indicates the light intensity, and the high level for the electric charge transfer timing to the first charge accumulation region FD-A and the electric charge transfer timing to the third charge accumulation region FD-C indicates the transfer of electric charges.

For example, when the electric charge transfer timing Qa is at high level, the electric charges are transferred to the first charge accumulation region FD-A, and when the electric charge transfer timing Qd is at high level, the electric charges are transferred to the third charge accumulation region FD-D. As illustrated in FIG. 12, in the comparative example described with reference to FIG. 11, the electric charges generated by the reflected light move back to the first charge accumulation region FD-A at the electric charge transfer timing Qd, and are accumulated in the first charge accumulation region FD-A. For example, even when 10 charges are generated at the electric charge transfer timing Qd, for example, 2 charges move back to the first charge accumulation region FD-A and are accumulated there. As a result, an electric charge distribution efficiency Cmod is reduced, represented by Expression (1):

$$[ Math . 1 ]$$

$$σ depth ∝ \frac{1}{Fmod} \times \frac{1}{Cmod} \qquad ( 1 )$$

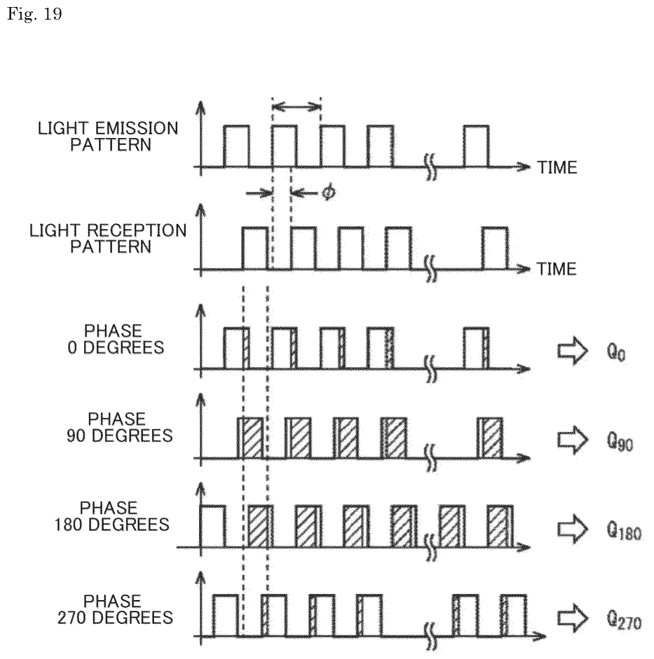

Expression (1) represents a relationship between a distance measurement error σdepth, a drive frequency Fmod, and the electric charge distribution efficiency Cmod. As represented by Expression (1), the distance measurement error σdepth decreases as the drive frequency Fmod becomes higher. The distance measurement error σdepth decreases as the electric charge distribution efficiency Cmod becomes higher. On the other hand, as in the comparative example, the electric charge distribution efficiency Cmod is reduced as the drive frequency Fmod becomes higher. As a result, even when the drive frequency Fmod is made higher, the distance measurement error σdepth does not decrease. The efficiency Cmod is represented by Equations (2) to (4). Q0, Q90, Q180, and Q270 will be described later with reference to FIG. 19.

$$[ Math . 2 ]$$

$$Cmod = \{ ( I - Q ) / ( I + Q ) \} \times 100 \qquad ( 2 )$$

$$[ Math . 3 ]$$

$$I = Q 0 - Q 180 \qquad ( 3 )$$

$$[ Math . 4 ]$$

$$Q = Q 90 - Q 270 \qquad ( 4 )$$

In contrast, in the present embodiment, the electric charges generated in the photoelectric conversion unit 80 reach the third conductor DTIC-C in the horizontal direction over the shortest distance. Then, they are vertically transferred. The electric potential has an electric potential gradient as represented by the shape on the right side of FIG. 10. Thus, even when the drive frequency Fmod is further increased, the electric charges that have reached the third conductor DTIC-C side are vertically transferred to the third charge accumulation region FD-C without moving to the first charge accumulation region FD-A side. As can be seen from this, even when the drive frequency Fmod is further increased, a decrease in the electric charge distribution efficiency Cmod is suppressed by switching the electric potentials to be formed in a time series as illustrated in FIGS. 9 and 10, for example. In addition, since electric charges are allowed to be horizontally transferred, it becomes possible to move the openings formed by the fifth conductor DTIC-0, the sixth conductor DTIC-1, the seventh conductor DTIC-2, and the eighth conductor DTIC-3 over the shortest distance, thereby further suppressing a decrease in the electric charge distribution efficiency Cmod even when the drive frequency Fmod is further increased.

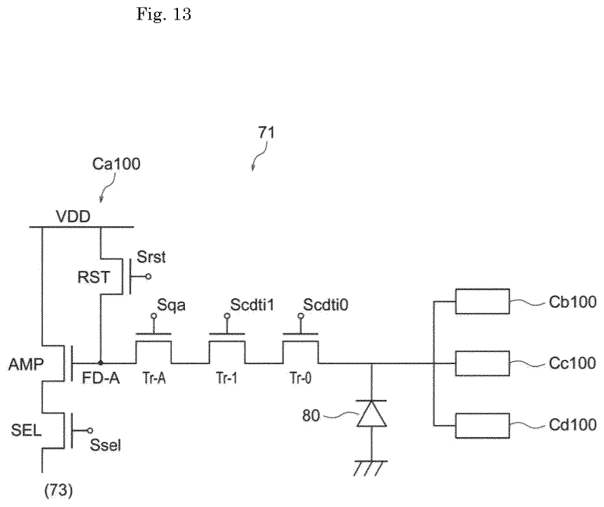

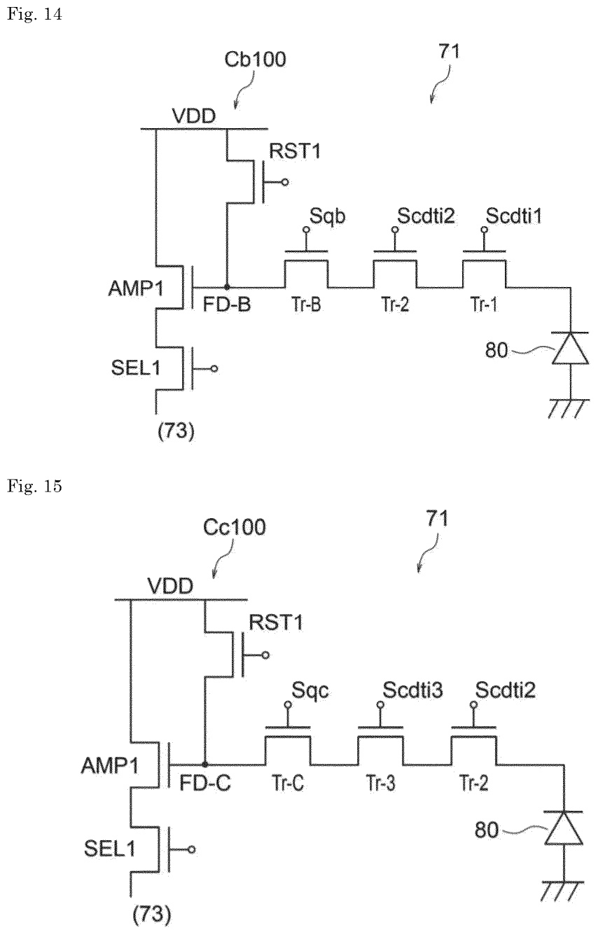

An equivalent circuit example of the pixel 71 will now be described with reference to FIGS. 13 to 16. FIG. 13 is a diagram illustrating a circuit configuration example of the pixel 71. As illustrated in FIG. 13, the electric charges generated in the photoelectric conversion unit 80 are output to the AD conversion unit 64 via a plurality of pixel circuits Ca100, Cb100, Cc100, and Cd100 and the respective vertical signal lines 73. The pixel circuits Ca100, Cb100, Cc100, and Cd100 are used for charge transfer of the first charge accumulation region FD-A, the second charge accumulation region FD-B, the third charge accumulation region FD-C, and the fourth charge accumulation region FD-D, respectively.

The pixel circuit Ca100 includes transfer transistors Tr-0, Tr-1, and Tr-A, the first charge accumulation region FD-A, a reset transistor RST, an amplifier transistor AMP, and a selection transistor SEL. The transfer transistors Tr-0, Tr-1, and Tr-A are connected in series, one end of which is connected to the photoelectric conversion unit 80, and the other end of which is connected to the first charge accumulation region FD-A. When the transfer transistors Tr-A to Tr-D enter a conductive state, an electric potential is formed toward the charge accumulation regions FD-A to FD-D, and the generated electric charges are vertically transferred.

Control signals Scdti0, Scdti1, and Sqa are supplied to the gates of the transfer transistors Tr-0, Tr-1, and Tr-A from the row scanning circuit 62, respectively. When the control signals Sqa, Scdti1, and Scdti0 are at high level, the transistors enter a conductive state. In other words, the transfer transistors Tr-0 and Tr-1 are synchronized with switching elements TGa-0 and TGb-0 and switching elements TGa-1 and TGb-1 (see FIG. 9).

The reset transistor RST has one end connected to the first charge accumulation region FD-A and the other end connected to a voltage source VDD. When a control signal Srst supplied to the gate electrode from the row scanning circuit 62 is at high level, the reset transistor RST enters a conductive state, and discharges the accumulated charges in the first charge accumulation region FD-A to reset, accordingly. In other words, when starting measurement for a pixel 71, the row scanning circuit 62 first resets the pixel 71.

The amplifier transistor AMP has one end connected to the voltage source VDD and the other end connected to the vertical signal line 73 via the selection transistor SEL. The selection transistor SEL is connected between the source electrode of the amplifier transistor AMP and the vertical signal line 73. When a control signal Ssel supplied to the gate electrode from the row scanning circuit 62 is at high level, the selection transistor SEL enters a conductive state, and outputs a detection signal output from the amplifier transistor AMP to the vertical signal line 73, accordingly. In other words, when the measurement for the pixel 71 is completed, the row scanning circuit 62 sets the control signal Ssel to high level, and outputs the detection signal to the vertical signal line 73. The row scanning circuit 62 sets the control signal Ssel to high level in the order of the pixel circuits Ca100, Cb100, Cc100, and Cd100, and outputs the detection signal to the vertical signal line 73.

FIG. 14 is a diagram illustrating a configuration example of the pixel circuit Cb100. The pixel circuit Cb100 has substantially the same configuration as the pixel circuit Ca100. Specifically, the pixel circuit Cb100 includes transfer transistors Tr-1, Tr-2, and Tr-B, the second charge accumulation region FD-B, a reset transistor RST, an amplifier transistor AMP, and a selection transistor SEL. The transfer transistors Tr-1, Tr-2, and Tr-B are connected in series, one end of which is connected to the photoelectric conversion unit 80, and the other end of which is connected to the second charge accumulation region FD-B.

Control signals Scdti1, Scdti2, and Sqb are supplied from the row scanning circuit 62 to the gates of the transfer transistors Tr-1, Tr-2, and Tr-B, respectively.

FIG. 15 is a diagram illustrating a configuration example of the pixel circuit Cc100. The pixel circuit Cb100 has substantially the same configuration as the pixel circuit Ca100. Specifically, the pixel circuit Cc100 includes transfer transistors Tr-2, Tr-3, and Tr-B, the third charge accumulation region FD-C, a reset transistor RST, an amplifier transistor AMP, and a selection transistor SEL. The transfer transistors Tr-2, Tr-3, and Tr-B are connected in series, one end of which is connected to the photoelectric conversion unit 80, and the other end of which is connected to the third charge accumulation region FD-C.

Control signals Scdti2, Scdti3, and Sqc are supplied from the row scanning circuit 62 to the gates of the transfer transistors Tr-2, Tr-3, and Tr-C, respectively.

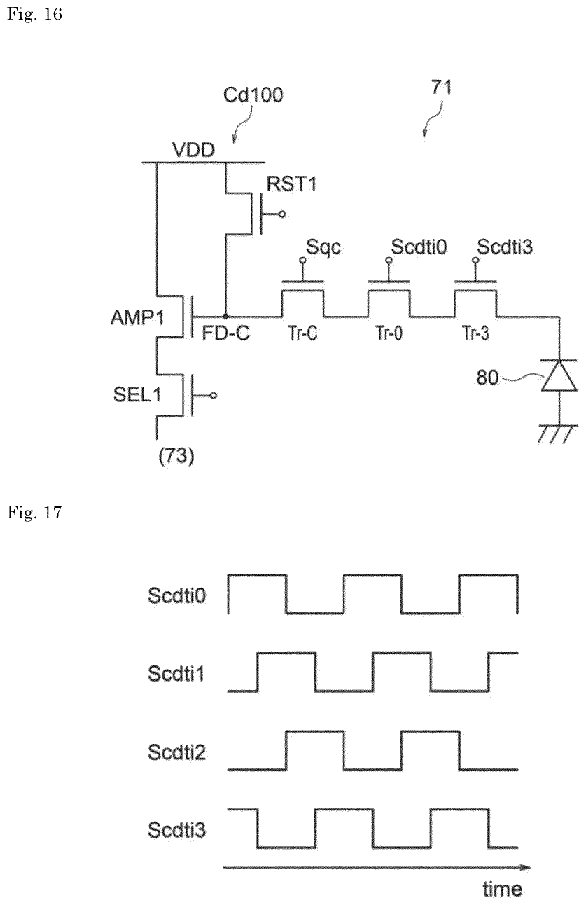

FIG. 16 is a diagram illustrating a configuration example of the pixel circuit Cd100. The pixel circuit Cd100 has substantially the same configuration as the pixel circuit Ca100. Specifically, the pixel circuit Cd100 includes transfer transistors Tr-3, Tr-0, and Tr-D, the fourth charge accumulation region FD-D, a reset transistor RST, an amplifier transistor AMP, and a selection transistor SEL. The transfer transistors Tr-2, Tr-3, and Tr-B are connected in series, one end of which is connected to the photoelectric conversion unit 80, and the other end of which is connected to the second charge accumulation region FD-D.

Control signals Scdti3, Scdti0, and Sqd are supplied from the row scanning circuit 62 to the gates of the transfer transistors Tr-3, Tr-0, and Tr-D, respectively. The circuit configuration examples of the pixel 71 are merely examples, and the circuit configuration is not limited to these.

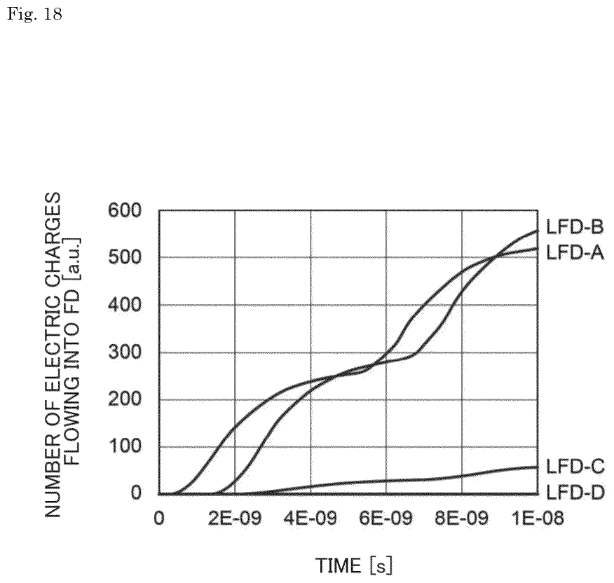

A control operation example of the distance measuring device 10 will now be described with reference to FIGS. 17 and 18. FIG. 17 illustrates an example of the control signals Scdti0, Scdti1, Scdti2, and Scdti3 supplied from the row scanning circuit 62. The control signals Scdti0, Scdti1, Scdti2, and Scdti3 are indicated in order from the top. The horizontal axis represents time. The control signals Scdti0, Scdti1, Scdti2, and Scdti3 have the same cycle, and their phases differ from one another by 90 degrees.

Referring again to FIG. 9, when the control signal Scdti0 is at high level, the fifth conductor DTIC-0 is in an ON state, and when the control signal Scdti0 is at low level, the fifth conductor DTIC-0 is in an OFF state. Similarly, when the control signal Scdti1 is at high level, the sixth conductor DTIC-1 is in an ON state, and when the control signal Scdti1 is at low level, the sixth conductor DTIC-1 is in an OFF state. Similarly, when the control signal Scdti2 is at high level, the seventh conductor DTIC-2 is in an ON state, and when the control signal Scdti2 is at low level, the seventh conductor DTIC-2 is in an OFF state. Similarly, when the control signal Scdti2 is at high level, the eighth conductor DTIC-3 is in an ON state, and when the control signal Scdti2 is at low level, the eighth conductor DTIC-3 is in an OFF state. The high level periods of the transfer transistors Tr-0 to Tr-3 and Tr-A to Tr-D may be increased in consideration of the vertical transfer time of electrons in the photoelectric conversion unit 80.

As can be seen from this, when the control signals Scdti0 and Scdti1 are both at high level, the electric charges are transferred to the first charge accumulation region FD-A side, when the control signals Scdti1 and Scdti2 are both at high level, the electric charges are transferred to the second charge accumulation region FD-B side, when the control signals Scdti2 and Scdti3 are both at high level, the electric charges are transferred to the third charge accumulation region FD-C side, and when the control signals Scdti3 and Scdti0 are both at high level, the electric charges are transferred to the fourth charge accumulation region FD-D side.

The control signals Sqa, Sqb, Sqc, and Sqd are always maintained at high level while the pixel 71 is being driven. As described above, an electric potential toward the first charge accumulation region FD-A is formed while the pixel 71 is being driven, and the generated electric charges are vertically transferred. Thus, the electric charges are transferred to the first charge accumulation region FD-A, the second charge accumulation region FD-B, the third charge accumulation region FD-C, and the fourth charge accumulation region FD-D.

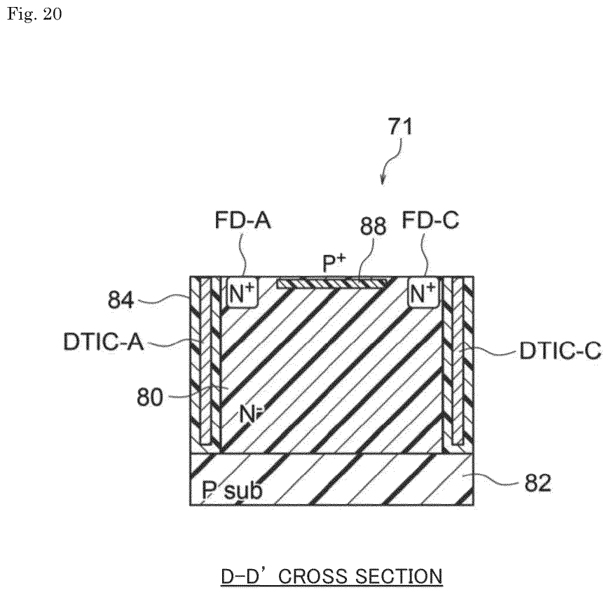

FIG. 18 is a diagram schematically illustrating the number of electric charges flowing into each of the first charge accumulation region FD-A, the second charge accumulation region FD-B, the third charge accumulation region FD-C, and the fourth charge accumulation region FD-D when the drive is repeated using the control signals indicated in FIGS. 17 and 20. The vertical axis represents the number of electric charges, and the horizontal axis represents time. The numbers of charges flowing into the first charge accumulation region FD-A, the second charge accumulation region FD-B, the third charge accumulation region FD-C, and the fourth charge accumulation region FD-D are indicated by lines LFD-A, LFD-B, LFD-C and LFD-D, respectively. In this way, different electric charges are accumulated in the first charge accumulation region FD-A, the second charge accumulation region FD-B, the third charge accumulation region FD-C, and the fourth charge accumulation region FD-D depending on the phases of the control signals Scdti0, Scdti1, Scdti2, and Scdti3, respectively.

FIG. 19 illustrates a relationship between a light emission pattern of the light emitting source 31 and detection signals at the pixel 71. From the top, the light emission pattern of the light emitting source 31, a light reception pattern which indicates the timing at which the light emission pattern is received by the pixel 71, and the detection signals of a phase of 0 degrees, a phase of 90 degrees, a phase of 180 degrees, and a phase of 270 degrees are indicated. The vertical axis of each signal represents high level and low level, and the horizontal axis represents time. The high level of the light emission pattern indicates a time of pattern light 15 (see FIG. 1) emitted, and the high level of the light reception pattern indicates a time of the pattern light 15 reflected and returned. In other words, in the present embodiment, a pulsed light that is repeatedly turned on and off at a frequency f (modulation frequency) at high speed is adopted. One cycle T of the pulsed light is 1/f. In the pixel 71, the phase of the reflected light (light reception pattern) to be detected is shifted according to a time Δt from the light emitting source 31 to the light receiving element 42.

The high level of the detection signal with a phase of 0 degrees indicates the timing of light reception at the pixel 71. In other words, this is the timing with the phase of the pulsed light emitted by the light emitting source 31 of the light source unit 11, that is, the same as the phase of the light emission pattern.

Similarly, the high level of the detection signal with a phase of 90 degrees is the timing with the phase delayed by 90 degrees from the pulsed light (light emission pattern) emitted by the light emitting source 31 of the light source unit 11. Similarly, the high level of the detection signal with a phase of 180 degrees is the timing with the phase delayed by 180 degrees from the pulsed light (light emission pattern) emitted by the light emitting source 31 of the light source unit 11. Similarly, the high level of the detection signal with a phase of 270 degrees is the timing with the phase delayed by 270 degrees from the pulsed light (light emission pattern) emitted by the light emitting source 31 of the light source unit 11.

Measurement signals corresponding to the electric charges accumulated in the case where the light reception timings are set to a phase of 0 degrees, a phase of 90 degrees, a phase of 180 degrees, and a phase of 270 degrees are referred to as Q0, Q90, Q180, and Q270, respectively.

In this case, there are relationships: Q0=QA+QB, Q90=QB+QC, Q180=QC+QD, and Q270=QD+QA. QA is a value obtained by converting the detection signal detected from the first charge accumulation region FD-A at the end of the measurement into a digital signal by the AD conversion unit 64. Similarly, QB is a value obtained by converting the detection signal detected from the third charge accumulation region FD-B at the end of the measurement into a digital signal by the AD conversion unit 64. Similarly, QC is a value obtained by converting the detection signal detected from the third charge accumulation region FD-C at the end of the measurement into a digital signal by the AD conversion unit 64. Similarly, QD is a value obtained by converting the detection signal detected from the fourth charge accumulation region FD-D at the end of the measurement into a digital signal by the AD conversion unit 64.

These signals corresponding to the electric charges are stored in the storage unit 44 as measurement signals Q0(x, y), Q90(x, y), Q180(x, y), and Q270(x, y) for each pixel I(x, y).

Details of the signal processing unit 43 will now be described. First, a method of distance measurement using the ToF method will be described.

A distance measurement value D(x, y) [mm], which corresponds to a distance from the distance measuring unit 21 to a target object, can be calculated by the following Equation (5):

$$[ Math . 5 ]$$

$$D ( x , y ) = 1 / ( 2 c \times Δ t ( x , y ) ) \qquad ( 5 )$$

In Equation (1), Δt(x, y) is a time between when the pattern light 15 is emitted from the light emitting source 31 and when it is reflected by the target object and then enters each pixel (x, y) of the light receiving element 42, and c represents the speed of light. (x, y) is the coordinates of the pixel 71.

As the pattern light 15 emitted from the light emitting source 31, pulsed light is adopted that is repeatedly turned on and off at high speed at a predetermined frequency f (modulation frequency) as indicated in FIG. 19. One cycle T of the pulsed light is 1/f. In the light receiving element 42, the phase of the reflected light (received light pattern) to be detected is shifted according to a time Δt(x, y) from the light emitting source 31 to the light receiving element 42 reached. When the amount of phase shift (phase difference) between the light emission pattern and the light receiving pattern is φ(x, y), the time Δt(x, y) can be calculated by the following Equation (6):

$$[ Math . 6 ]$$

$$Δ t ( x , y ) = ϕ ( x , y ) / 2 π f \qquad ( 6 )$$

Therefore, a distance measurement value Da(x, y) from the light receiving element 42 to the target object can be calculated from Equations (4) and (6) using the following Equation (7):

$$[ Math . 7 ]$$

$$Da ( x , y ) = ( c \times ϕ ( x , y ) ) / 4 π f \qquad ( 7 )$$

FIG. 9 illustrates a phase difference φ generated a phase generation unit 437. As illustrated in FIG. 9, the phase generation unit 437 calculates a phase difference φ(x, y) at the pixel I(x, y) by the following Equation (8) using the measurement signals Q0(x, y), Q90(x, y), Q180(x, y), and Q270(x, y):

$$[ Math . 8 ]$$

$$ϕ ( x , y ) = Arc tan ( Q 90 ( x , y ) - Q 270 ( x , y ) ) / ( Q 180 ( x , y ) - Q 0 ( x , y ) ) \qquad ( 8 )$$

The phase difference φ(x, y) calculated by Equation (8) can be applied to Equation (7) above to calculate the distance measurement value Da(x, y) from the distance measuring device 10 to the target object. The signal processing unit 43 can store the distance measurement value Da(x, y) in the storage unit 44 as a two-dimensional distance image, and display it on the display device 51.

As described above, according to the present embodiment, the first conductor DTIC-A, the second conductor DTIC-B, the third conductor DTIC-C, the fourth conductor DTIC-D, the fifth conductor DTIC-0, the sixth conductor DTIC-1, the seventh conductor DTIC-2, and the eighth conductor DTIC-3 are formed running from the upper surface to the lower surface of the photoelectric conversion unit 80. Thus, by changing the combination of voltages applied to the first conductor DTIC-A, the second conductor DTIC-B, the third conductor DTIC-C, the fourth conductor DTIC-D, the fifth conductor DTIC-0, the sixth conductor DTIC-1, the seventh conductor DTIC-2, and the eighth conductor DTIC-3 in a time series, it is possible to form an electric potential with which electric charges are to be transferred horizontally in any of the directions of the first conductor DTIC-A, the second conductor DTIC-B, the third conductor DTIC-C, and the fourth conductor DTIC-D, in the horizontal direction from the upper surface to the lower surface of the photoelectric conversion unit 80. Thus, electric charges can be horizontally transferred over the shortest distance to any of the first conductor DTIC-A, the second conductor DTIC-B, the third conductor DTIC-C, and the fourth conductor DTIC-D through an opening formed by any of the fifth conductor DTIC-0, the sixth conductor DTIC-1, the seventh conductor DTIC-2, and the eighth conductor DTIC-3. As a result, a decrease in the electric charge distribution efficiency is suppressed.

In addition, by applying a voltage to the fifth conductor DTIC-0, the sixth conductor DTIC-1, the seventh conductor DTIC-2, and the eighth conductor DTIC-3, the electric charges transferred horizontally through an opening formed by any of the fifth conductor DTIC-0, the sixth conductor DTIC-1, the seventh conductor DTIC-2, and the eighth conductor DTIC-3 to any of the first conductor DTIC-A, the second conductor DTIC-B, the third conductor DTIC-C, and the fourth conductor DTIC-D over the shortest distance is prevented from being re-transferred to other conductors. As a result, a decrease in the electric charge distribution efficiency is further suppressed.

### Modification Example 1 of First Embodiment

A distance measuring device 10 according to Modification Example 1 of the first embodiment differs from the distance measuring device 10 according to the first embodiment in that a P-type impurity region 88 is further formed on the outermost surface of the photoelectric conversion unit 80 of the pixel 71. Differences from the distance measuring device 10 according to the first embodiment will be described below.

FIG. 20 is a diagram illustrating a DD cross section (see FIG. 5) of the pixel 71. As illustrated in FIG. 20, the distance measuring device 10 according to Modification Example 1 of the first embodiment has the P-type impurity region 88 on the outermost surface of the photoelectric conversion unit 80 of the pixel 71. This makes it possible to prevent the generation of dark electrons that are generated at the interface on the surface side of the photoelectric conversion unit 80. Thus, it is possible to suppress a decrease in the S/N ratio due to the dark electrons of the pixel 71, and to suppress a decrease in the distance measurement error σdepth (see Expression (1)).

### Second Embodiment

A distance measuring device 10 according to a second embodiment differs from the distance measuring device 10 according to the first embodiment in that it is of a back-illuminated type. Differences from the distance measuring device 10 according to the first embodiment will be described below.

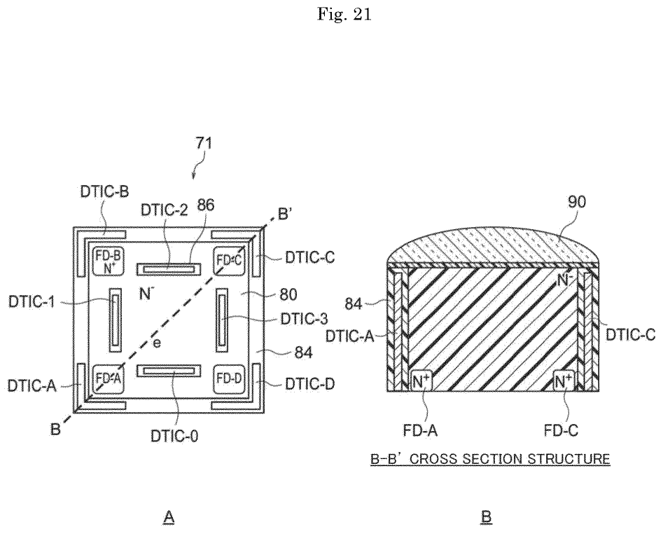

FIG. 21 is a diagram illustrating a configuration example of a pixel 71 according to the second embodiment. Figure A is a plan view illustrating a configuration example of the pixel 71 according to the second embodiment. Figure B is a cross-sectional view taken along BB.

In the pixel 71 according to the second embodiment, reflected light is incident from the back surface side, which is the opposite side to the substrate side on which the circuits and others are arranged. Therefore, the pixel 71 differs from the distance measuring device 10 according to the first embodiment in that the first charge accumulation region FD-A, the second charge accumulation region FD-B, the third charge accumulation region FD-C, and the fourth charge accumulation region FD-D are arranged on the substrate 82 side of the photoelectric conversion unit 80. This allows for simplified wiring of the circuits Ca100 to Cd100 (see FIG. 13). In addition, it is possible to prevent the reflection of incident light by the wiring layer, which would cause a decrease in the amount of light incident onto the photoelectric conversion unit 80, thereby increasing Qe.

The pixel 71 according to the second embodiment further includes an on-chip lens 90 on the back surface side of the photoelectric conversion unit 80 onto which reflected light is incident. In the pixel 71 according to the second embodiment, reflected light is incident from the back surface side opposite to the substrate side on which the circuits and others are arranged, so that it is possible to increase the aperture ratio of the pixel 71.

### Modification Example 1 of Second Embodiment

A distance measuring device 10 according to Modification Example 1 of the second embodiment differs from the distance measuring device 10 according to the second embodiment in that an insulating film 92 of a P-type impurity region is further formed on the outermost surface of the photoelectric conversion unit 80 of the pixel 71 on the substrate side. Differences from the distance measuring device 10 according to the second embodiment will be described below.

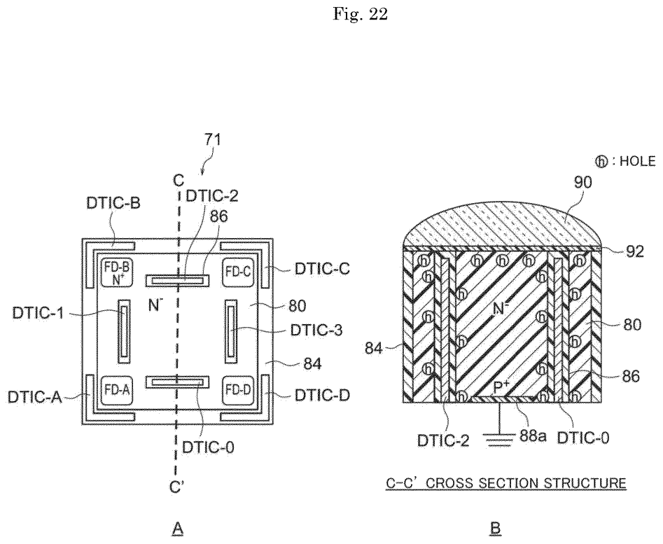

FIG. 22 is a diagram illustrating a configuration example of a pixel 71 according to Modification Example 1 of the second embodiment. Figure A is a plan view illustrating a configuration example of the pixel 71 according to the second embodiment. Figure B is a cross-sectional view taken along CC.

As illustrated in FIG. 22, the distance measuring device 10 according to the Modification Example 1 of the second embodiment further includes an insulating film 92 having a negative fixed electric potential on the outermost surface of the photoelectric conversion unit 80 of the pixel 71 on an on-chip lens 90 side, and induces holes at the interface with the photoelectric conversion unit 80. It also includes a P-type impurity region 88a on the outermost surface of the photoelectric conversion unit 80 of the pixel 71 on the substrate side. Conduction to GND is achieved through holes induced on the side walls of DTIC-0 to DTIC-3. In this way, holes can be generated in the photoelectric conversion unit 80, making it possible to prevent the generation of dark electrons. This makes it possible to suppress a decrease in the S/N ratio of the pixel 71, and to suppress a decrease in the distance measurement error σdepth (see Expression (1)).

### Third Embodiment

A distance measuring device 10 according to a third embodiment differs from the distance measuring device 10 according to the first embodiment in that a plurality of conductors are formed in an I-shaped trench. Differences from the distance measuring device 10 according to the first embodiment will be described below.

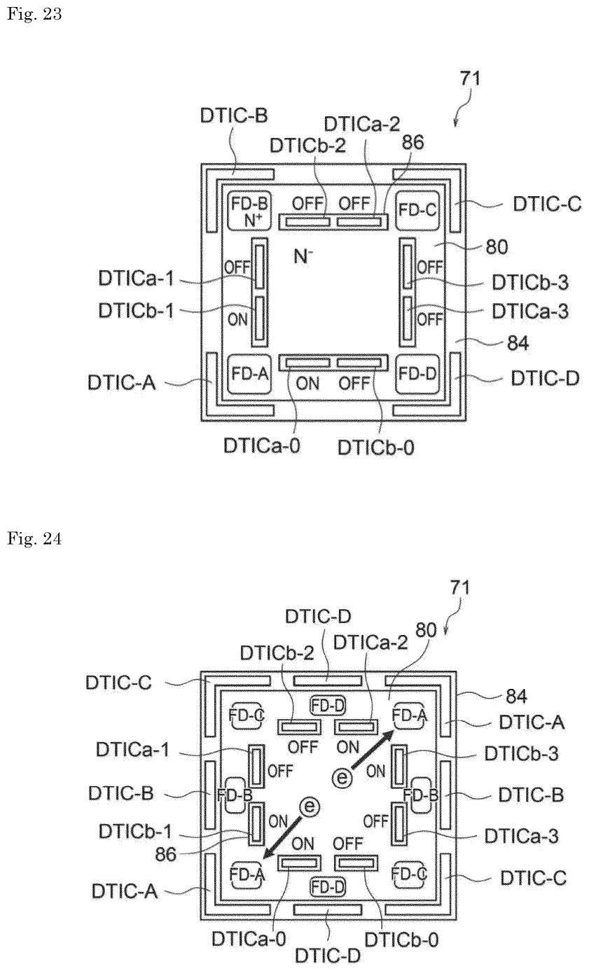

FIG. 23 is a plan view illustrating a configuration of a pixel 71 according to the third embodiment. As illustrated in FIG. 23, in the pixel 71 according to the third embodiment, a plurality of conductors are formed in the I-shaped trench of each of the second insulators 86 spaced apart from one another. Specifically, a ninth conductor DTICa-0, a tenth conductor DTICb-0, an eleventh conductor DTICa-1, a twelfth conductor DTICb-1, a thirteenth conductor DTICa-2, a fourteenth conductor DTICb-2, a fifteenth conductor DTICa-3, and a sixteenth conductor DTICb-3 are provided.

Here, a first group G1 is a combination of (the ninth conductor DTICa-0, the twelfth conductor DTICb-1), a second group G2 is a combination of (the eleventh conductor DTICa-1, the fourteenth conductor DTICb-2), a third group G3 is a combination of (the thirteenth conductor DTICa-2, the sixteenth conductor DTICb-3), and a fourth group G4 is a combination of (the fifteenth conductor DTICa-3, the tenth conductor DTICb-0).

This enables the row scanning circuit 62 (see FIG. 4) to control the ON/OFF state for each group. For example, as illustrated in FIG. 19, it is possible to control the first group G1 to be in an ON state or an OFF state in accordance with the high level or low level of a signal with a phase of 0 degrees. Similarly, it is possible to control the first group G2 to be in an ON state or an OFF state in accordance with the high level or low level of a signal with a phase of 90 degrees. Similarly, it is possible to control the first group G3 to be in an ON state or an OFF state in accordance with the high level or low level of a signal with a phase of 180 degrees. Similarly, it is possible to control the fourth group G4 to be in an ON state or an OFF state in accordance with the high level or low level of a signal with a phase of 270 degrees.

Therefore, the separation of the electric charges into the first charge accumulation region FD-A, the second charge accumulation region FD-B, the third charge accumulation region FD-C, and the fourth charge accumulation region FD-D is further improved. As a result, the inflow of electric charges outside the target charge accumulation region can be further prevented, so that even when the drive frequency Fmod is further increased, a decrease in the electric charge distribution efficiency Cmod (see Expression 1) is further suppressed.

### Fourth Embodiment

A distance measuring device 10 according to a fourth embodiment differs from the distance measuring device 10 according to the first embodiment in that each of the first charge accumulation region FD-A, the second charge accumulation region FD-B, the third charge accumulation region FD-C, and the fourth charge accumulation region FD-D is configured to include a plurality of regions. Differences from the distance measuring device 10 according to the first embodiment will be described below.

FIG. 24 is a plan view illustrating a configuration of a pixel 71 according to the fourth embodiment. As illustrated in FIG. 24, in the pixel 71 according to the fourth embodiment, a plurality of conductors are formed in the I-shaped trench of each of the second insulators 86 spaced apart from one another. Specifically, a ninth conductor DTICa-0, a tenth conductor DTICb-0, an eleventh conductor DTICa-1, a twelfth conductor DTICb-1, a thirteenth conductor DTICa-2, a fourteenth conductor DTICb-2, a fifteenth conductor DTICa-3, and a sixteenth conductor DTICb-3 are provided. Furthermore, the ninth conductor DTICa-0 and the tenth conductor DTICb-0 are spaced apart to form an opening, the eleventh conductor DTICa-1 and the twelfth conductor DTICb-1 are spaced apart to form an opening, the thirteenth conductor DTICa-2 and the fourteenth conductor DTICb-2 are spaced apart to form an opening, and the fifteenth conductor DTICa-3 and the sixteenth conductor DTICb-3 are spaced apart to form an opening.

First charge accumulation regions FD-A, second charge accumulation regions FD-B, third charge accumulation regions FD-C, and fourth charge accumulation regions FD-D are each arranged in pairs at symmetric positions with respect to the center point of the photoelectric conversion unit 80. The paired first charge accumulation regions FD-A, the paired second charge accumulation regions FD-B, the paired third charge accumulation regions FD-C, and the paired fourth charge accumulation regions FD-D are each electrically connected to each other.

Here, a first group G1 is a combination of (the ninth conductor DTICa-0, the twelfth conductor DTICb-1, the thirteenth conductor DTICa-2, and the fifteenth conductor DTICb-3), a second group G2 is a combination of (the twelfth conductor DTICb-1, the eleventh conductor DTICa-1, the sixteenth conductor DTICb-3, and the fifteenth conductor DTICa-3), a third group G3 is a combination of (the fourteenth conductor DTICb-2, the thirteenth conductor DTICa-2, the tenth conductor DTICb-0, and the ninth conductor DTICa-0), and a fourth group G4 is a combination of (the fifteenth conductor DTICa-3, the tenth conductor DTICb-0, the eleventh conductor DTICa-1, and the fourteenth conductor DTICb-2).

This enables the row scanning circuit 62 (see FIG. 4) to control the ON/OFF state for each group. For example, as illustrated in FIG. 19, it is possible to control the first group G1 to be in an ON state or an OFF state in accordance with the high level or low level of a signal with a phase of 0 degrees. Similarly, it is possible to control the first group G2 to be in an ON state or an OFF state in accordance with the high level or low level of a signal with a phase of 90 degrees. Similarly, it is possible to control the first group G3 to be in an ON state or an OFF state in accordance with the high level or low level of a signal with a phase of 180 degrees. Similarly, it is possible to control the fourth group G4 to be in an ON state or an OFF state in accordance with the high level or low level of a signal with a phase of 270 degrees.

Therefore, to each of the two first charge accumulation regions FD-A, the electric charges are transferred from half the region of the photoelectric conversion unit 80 to the target. Similarly, to each of the two second charge accumulation regions FD-B, the electric charges are transferred from half the region of the photoelectric conversion unit 80 to the target. Similarly, to each of the two third charge accumulation regions FD-C, the electric charges are transferred from half the region of the photoelectric conversion unit 80 to the target. Similarly, to each of the two fourth charge accumulation regions FD-D, the electric charges are transferred from half the region of the photoelectric conversion unit 80 to the target. Thus, the horizontal transfer time is further shortened, so that even when the drive frequency Fmod is further increased, a decrease in the electric charge distribution efficiency Cmod (see Expression 1) is further suppressed.

### Modification Example 1 of Fourth Embodiment

A distance measuring device 10 according to Modification Example 1 of the fourth embodiment differs from the distance measuring device 10 according to the fourth embodiment in that a conductor DTIC-M is further disposed in the center of the photoelectric conversion unit 80. Differences from the distance measuring device 10 according to the fourth embodiment will be described below.

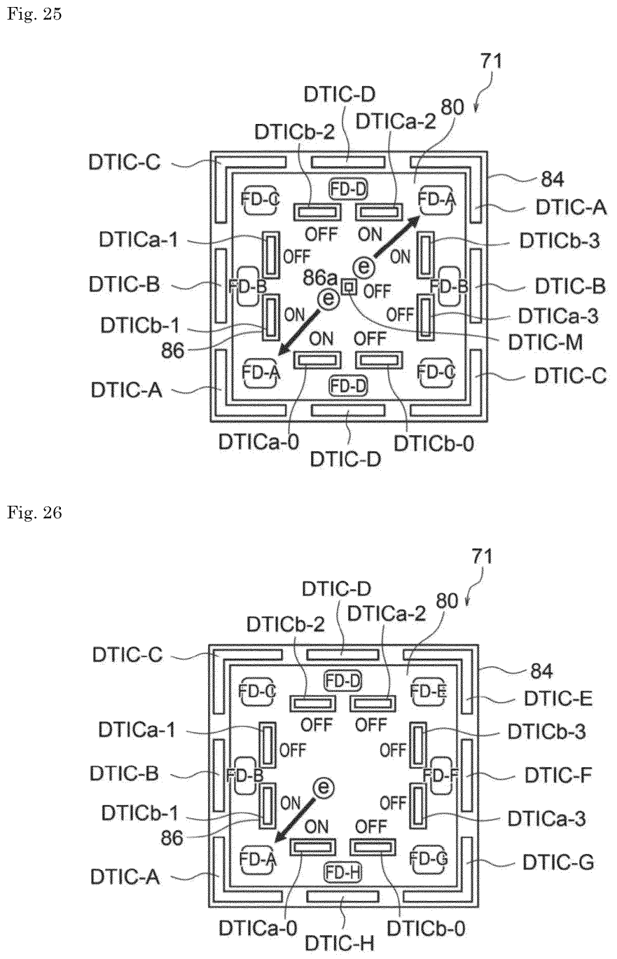

FIG. 25 is a diagram illustrating a configuration example of a pixel 71 according to Modification Example 1 of the fourth embodiment. As illustrated in FIG. 25, the pixel 71 according to Modification Example 1 of the fourth embodiment further includes the conductor DTIC-M having a square shape in the center of the photoelectric conversion unit 80. The conductor DTIC-M is formed running from the upper surface to the lower surface of the photoelectric conversion unit 80, and is surrounded by an insulator 86a.

The row scanning circuit 62 (see FIG. 4) applies, for example, −2.2 volts (OFF state) to the conductor DTIC-M as an electric potential corresponding to the OFF state. As a result, the electric potential gradient of the electric potential of a central portion where the conductor DTIC-M is disposed is shaped to further increase the acceleration of transferring electric charges to the peripheral portions. Accordingly, the horizontal transfer time is further shortened, so that even when the drive frequency Fmod is further increased, a decrease in the electric charge distribution efficiency Cmod (see Expression 1) is further suppressed.

### Fifth Embodiment

A distance measuring device 10 according to a fifth embodiment differs from the distance measuring device 10 according to the fourth embodiment in that each charge accumulation region accumulates electric charges independently. Differences from the distance measuring device 10 according to the fourth embodiment will be described below.

FIG. 26 is a plan view illustrating a configuration of a pixel 71 according to the fifth embodiment. As illustrated in FIG. 26, the pixel 71 according to the fifth embodiment has a first charge accumulation region FD-A, a second charge accumulation region FD-B, a third charge accumulation region FD-C, a fourth charge accumulation region FD-D, a fifth charge accumulation region FD-E, a sixth charge accumulation region FD-F, a seventh charge accumulation region FD-G, and an eighth charge accumulation region FD-H. The first charge accumulation region FD-A and the fifth charge accumulation region FD-E are arranged at symmetric positions with respect to the center point of the photoelectric conversion unit 80. Similarly, the second charge accumulation region FD-B and the sixth charge accumulation region FD-F are arranged at symmetric positions with respect to the center point of the photoelectric conversion unit 80. Similarly, the third charge accumulation region FD-C and the seventh charge accumulation region FD-G are arranged at symmetric positions with respect to the center point of the photoelectric conversion unit 80. Similarly, the fourth charge accumulation region FD-D and the eighth charge accumulation region FD-H are arranged at symmetric positions with respect to the center point of the photoelectric conversion unit 80.

Here, a first group G1 is a combination of (the ninth conductor DTICa-0 and the twelfth conductor DTICb-1), a second group G2 is a combination of (the twelfth conductor DTICb-1 and the eleventh conductor DTICa-1), a thirteenth group G3 is a combination of (the eleventh conductor DTICa-1 and the fourteenth conductor DTICb-2), and a fourth group G4 is a combination of (the fourteenth conductor DTICb-2 and the thirteenth conductor DTICa-2), a fifth group G5 is a combination of (the thirteenth conductor DTICa-2 and the sixteenth conductor DTICb-3), a sixth group G6 is a combination of (the sixteenth conductor DTICb-3 and the fifteenth conductor DTICa-3), a seventh group G7 is a combination of (the fifteenth conductor DTICa-3 and the tenth conductor DTICb-0), and an eighth group G8 is a combination of (the tenth conductor DTICb-0 and the ninth conductor DTICa-0).

This enables the row scanning circuit 62 (see FIG. 4) to control the ON/OFF state for each group. This makes it possible to configure the pixels 71 with a so-called 8Tap configuration. This also enables drive control for, for example, a signal with a phase of 0 degrees, a signal with a phase of 45 degrees, a signal with a phase of 90 degrees, a signal with a phase of 135 degrees, and a signal with a phase of 180 degrees (see FIG. 19), which differ from one another by 45 degrees in phase.

### Modification Example 1 of Fifth Embodiment

A distance measuring device 10 according to Modification Example 1 of the fifth embodiment differs from the distance measuring device 10 according to the fifth embodiment in that a conductor DTIC-M is further disposed in the center of the photoelectric conversion unit 80. Differences from the distance measuring device 10 according to the fourth embodiment will be described below.

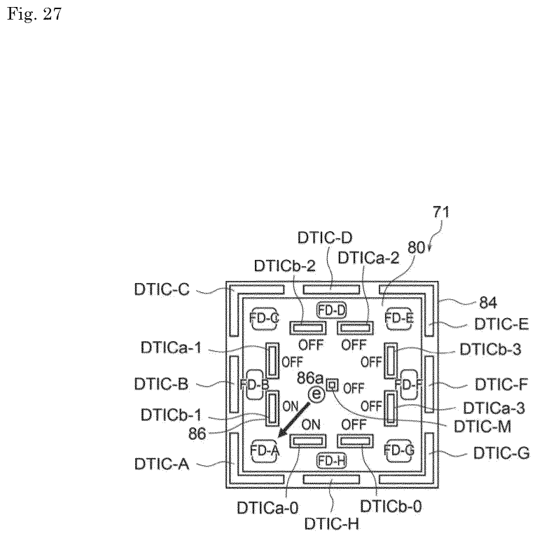

FIG. 27 is a diagram illustrating a configuration example of a pixel 71 according to Modification Example 1 of the fifth embodiment. As illustrated in FIG. 27, the pixel 71 according to Modification Example 1 of the fifth embodiment further includes the conductor DTIC-M having a square shape in the center of the photoelectric conversion unit 80. The conductor DTIC-M is formed running from the upper surface to the lower surface of the photoelectric conversion unit 80, and is surrounded by an insulator 86a.

The row scanning circuit 62 (see FIG. 4) applies, for example, −2.2 volts to the conductor DTIC-M as an electric potential corresponding to the OFF state. As a result, the gradient of the electric potential of a central portion where the conductor DTIC-M is disposed is shaped to further increase the acceleration of transferring electric charges to the periphery. Accordingly, the horizontal transfer time is further shortened, so that even when the drive frequency Fmod is further increased, a decrease in the electric charge distribution efficiency Cmod (see Expression 1) is further suppressed.

### Sixth Embodiment

A distance measuring device 10 according to a sixth embodiment differs from the distance measuring device 10 according to the first embodiment in that electric charges are accumulated in peripheral portions of the first conductor DTIC-A, the second conductor DTIC-B, the third conductor DTIC-C, and the fourth conductor DTIC-D, and then transferred to the first charge accumulation region FD-A, the second charge accumulation region FD-B, the third charge accumulation region FD-C, and the fourth charge accumulation region FD-D. Differences from the distance measuring device 10 according to the first embodiment will be described below.

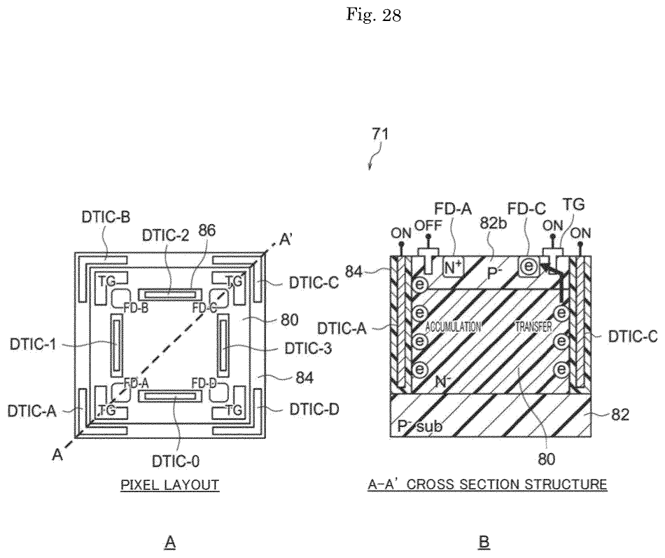

FIG. 28 is a diagram illustrating a configuration example of a pixel 71 according to the sixth embodiment. Figure A is a plan view of the pixel 71 according to the fifth embodiment, and Figure B is a cross section taken along A-A. As illustrated in FIG. 28, a second substrate 82b is configured as a P-semiconductor region, which is a second conductivity type region, above the photoelectric conversion unit 80.

The first charge accumulation region FD-A, the second charge accumulation region FD-B, the third charge accumulation region FD-C, and the fourth charge accumulation region FD-D are arranged in the upper layer of the second substrate 82b. Furthermore, the first charge accumulation region FD-A, the second charge accumulation region FD-B, the third charge accumulation region FD-C, and the fourth charge accumulation region FD-D are connected to the first and the fourth conductor DTIC-D, respectively, via a corresponding gate transistor TG.

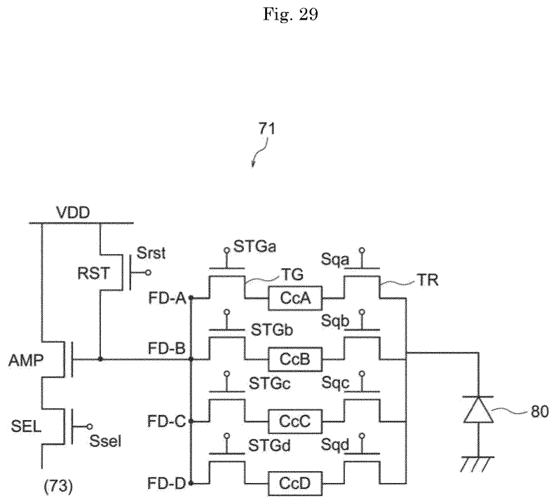

FIG. 29 is a diagram illustrating an equivalent circuit example of the pixel 71 according to the sixth embodiment. Capacitors Cca, Ccb, CcC, and CcD indicate the electric charge capacitances around the first conductor DTIC-A, the second conductor DTIC-B, the third conductor DTIC-C, and the fourth conductor DTIC-D, respectively. One ends of the transfer transistors are connected to the photoelectric conversion unit 80, and the other ends are connected to the capacitors Cca, Ccb, CcC, and CcD, respectively.

One ends of gate transistors TG are connected to the capacitors Cca, Ccb, CcC, and CcD, respectively, and the other ends are connected to the first charge accumulation region FD-A, the second charge accumulation region FD-B, the third charge accumulation region FD-C, and the fourth charge accumulation region FD-D, respectively. One end of the reset transistor RST is connected to the first charge accumulation region FD-A, the second charge accumulation region FD-B, the third charge accumulation region FD-C, and the fourth charge accumulation region FD-D.

As in the first embodiment, the amplifier transistor AMP has one end connected to the voltage source VDD and the other end connected to the vertical signal line 73 via the selection transistor SEL. The selection transistor SEL is connected between the source electrode of the amplifier transistor AMP and the vertical signal line 73. When a control signal Ssel supplied to the gate electrode from the row scanning circuit 62 is at high level, the selection transistor SEL enters a conductive state, and outputs a detection signal output from the amplifier transistor AMP to the vertical signal line 73, accordingly.

When a control signal Srst supplied to the gate electrode from the row scanning circuit 62 is at high level, the reset transistor RST enters a conductive state, and discharges the accumulated charges in the first charge accumulation region FD-A, the second charge accumulation region FD-B, the third charge accumulation region FD-C, and the fourth charge accumulation region FD-D to reset, accordingly. At this time, the row scanning circuit 62 supplies a high-level signal to each gate transistor TG, thereby discharging the accumulated charges in the capacitors Cca, Ccb, CcC, and CcD to reset.

As illustrated in FIG. 20, control signals Sqa, Sqb, Sqc, and Sqd are supplied to the gates of the transfer transistors, respectively, from the row scanning circuit 62. Thus, when the control signals Sqa, Sqb, Sqc, and Sqd are at high level, electric charges are accumulated in the capacitors Cca, Ccb, CcC, and CcD, respectively.

Then, after the measurement is completed, the row scanning circuit 62 again sets the reset transistor RST to high level to discharge the accumulated charges in the first charge accumulation region FD-A, the second charge accumulation region FD-B, the third charge accumulation region FD-C, and the fourth charge accumulation region FD-D to reset. Subsequently, a control signal STGa is set to high level to transfer the electric charges in the capacitor Cca to the first charge accumulation region FD-A, and a detection signal is output to the vertical signal line 73 via the amplifier transistor AMP.

Similarly, the row scanning circuit 62 again sets the reset transistor RST to high level to discharge the accumulated charges in the first charge accumulation region FD-A, the second charge accumulation region FD-B, the third charge accumulation region FD-C, and the fourth charge accumulation region FD-D to reset. Subsequently, a control signal STGb is set to high level to transfer the electric charges in the capacitance Ccb to the second charge accumulation region FD-B, and a detection signal is output to the vertical signal line 73 via the amplifier transistor AMP. Repeating such an operation makes it possible to read out the accumulated charges in each of the capacitors Cca, Ccb, CcC, and CcD as a detection signal. As can be seen from these, by accumulating electric charges in the capacitors Cca, Ccb, CcC, and CcD, it is possible to share the reset transistor RS, the amplifier transistor AMP, and the selection transistor SEL. This makes it possible to eliminate amplifier gain errors compared to the case where an amplifier is configured for each of the first charge accumulation region FD-A, the second charge accumulation region FD-B, the third charge accumulation region FD-C, and the fourth charge accumulation region FD-D. Therefore, the distance measurement error σdepth (see Expression (1)) can be further suppressed.

### Modification Example 1 of Sixth Embodiment

A distance measuring device 10 according to Modification Example 1 of the sixth embodiment differs from the distance measuring device 10 according to the sixth embodiment in that electric charges are accumulated in memories of embedded type and then transferred to the first charge accumulation region FD-A, the second charge accumulation region FD-B, the third charge accumulation region FD-C, and the fourth charge accumulation region FD-D. Differences from the distance measuring device 10 according to the sixth embodiment will be described below.

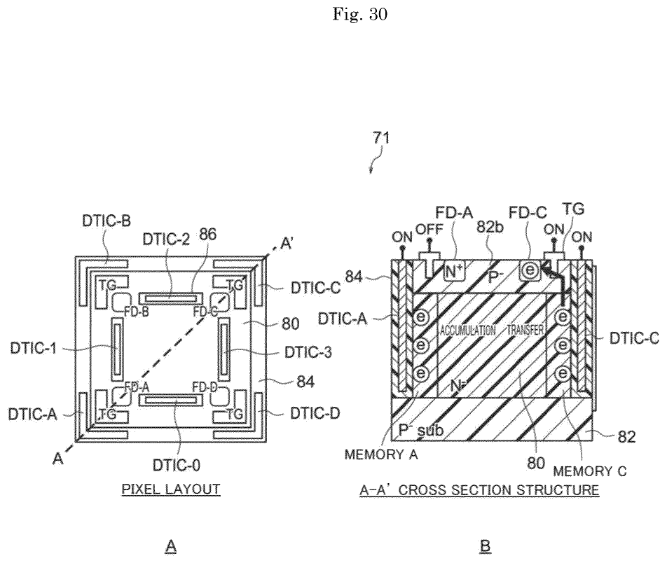

FIG. 30 is a diagram illustrating a configuration example of a pixel 71 according to Modification Example 1 of the sixth embodiment. Figure A is a plan view of the pixel 71 according to Modification Example 1 of the sixth embodiment, and Figure B is a cross section taken along A-A. As illustrated in FIG. 30, a memory A, a memory B, a memory C, and a memory D, which are of embedded type, are arranged adjacent to the first conductor DTIC-A, the second conductor DTIC-B, the third conductor DTIC-C, and the fourth conductor DTIC-D, respectively, via the first insulator 84.

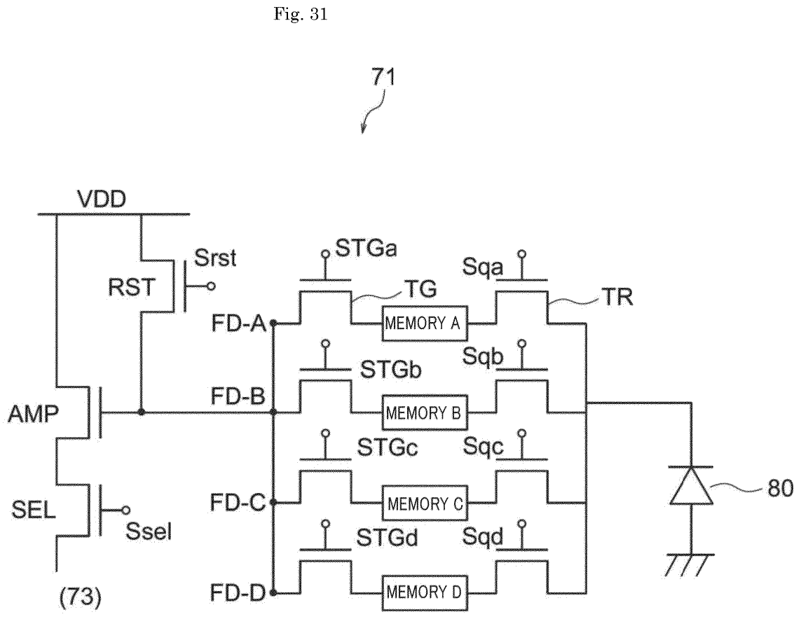

FIG. 31 is a diagram illustrating an equivalent circuit example of the pixel 71 according to Modification Example 1 of the sixth embodiment. One ends of transfer transistors TR are connected to the photoelectric conversion unit 80, and the other ends are connected to the memory A, the memory B, the memory C, and the memory D, respectively. One ends of gate transistors TG are connected to the memory A, the memory B, the memory C, and the memory D, respectively, and the other ends are connected to the first charge accumulation region FD-A, the second charge accumulation region FD-B, the third charge accumulation region FD-C, and the fourth charge accumulation region FD-D, respectively. The subsequent operation is the same as that of the pixel 71 according to the sixth embodiment.

By the memory A, the memory B, the memory C, and the memory D, which are of embedded type, arranged, it is possible to prevent the generation of dark electrons that occur during vertical transfer of electric charges. Therefore, the distance measurement error σdepth (see Expression (1)) can be further suppressed.

### Modification Example 2 of Sixth Embodiment

A distance measuring device 10 according to Modification Example 2 of the sixth modification differs from the distance measuring device 10 according to Modification Example 1 of the sixth embodiment in that the first insulator 84 and the second insulator 86 are connected as an insulator. Differences from the distance measuring device 10 according to Modification Example 1 of the sixth embodiment will be described below.

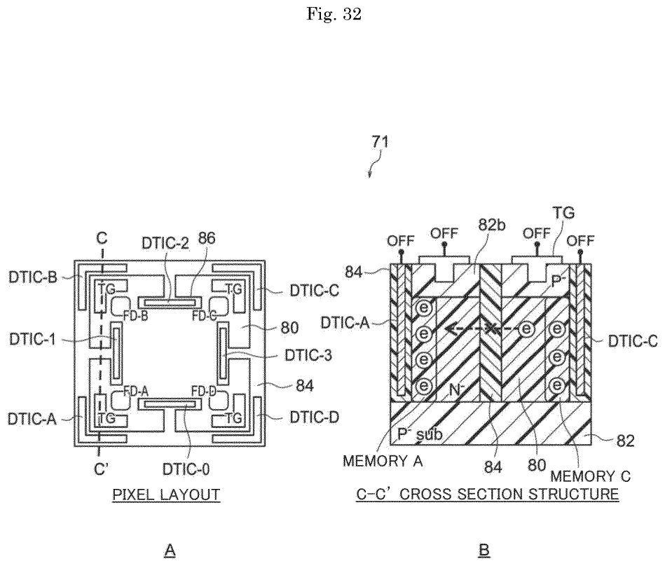

FIG. 32 is a diagram illustrating a configuration example of a pixel 71 according to Modification Example 2 of the sixth embodiment. Figure A is a plan view of the pixel 71 according to Modification Example 1 of the sixth embodiment, and Figure B is a cross section taken along A-A. As illustrated in FIG. 32, the first insulator 84 and the second insulator 86 are configured as an integrated insulator. As illustrated in Figure B, the insulator 84 can suppress the movement of electric charges between the memory A, the memory B, the memory C, and the memory D, which are of embedded type. This can suppress crosstalk between the memory A, the memory B, the memory C, and the memory D. Therefore, even when the drive frequency Fmod is further increased, a decrease in the electric charge distribution efficiency Cmod (see Expression 1) is further suppressed.

### Seventh Embodiment

A distance measuring device 10 according to a seventh embodiment differs from the distance measuring device 10 according to Modification Example 1 of the second embodiment in that the circuit configuration is configured within the substrate on the opposite side to the on-chip lens 90. Differences from the distance measuring device 10 according to Modification Example 1 of the second embodiment will be described below.

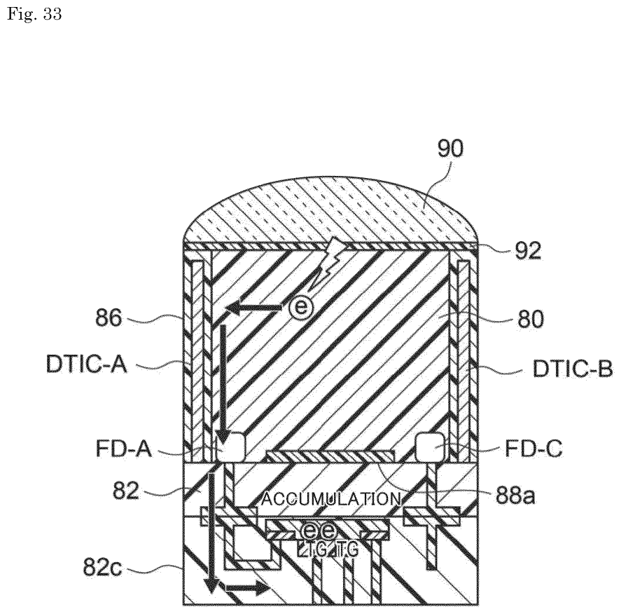

FIG. 33 is a cross-sectional view taken along CC (see FIG. 21) of the pixel 71 according to Modification Example 1 of the second embodiment. As illustrated in FIG. 33, the distance measuring device 10 according to the seventh embodiment includes a substrate 82 and a substrate 82c. For example, the substrate 82c is configured as a so-called TERIS structure.

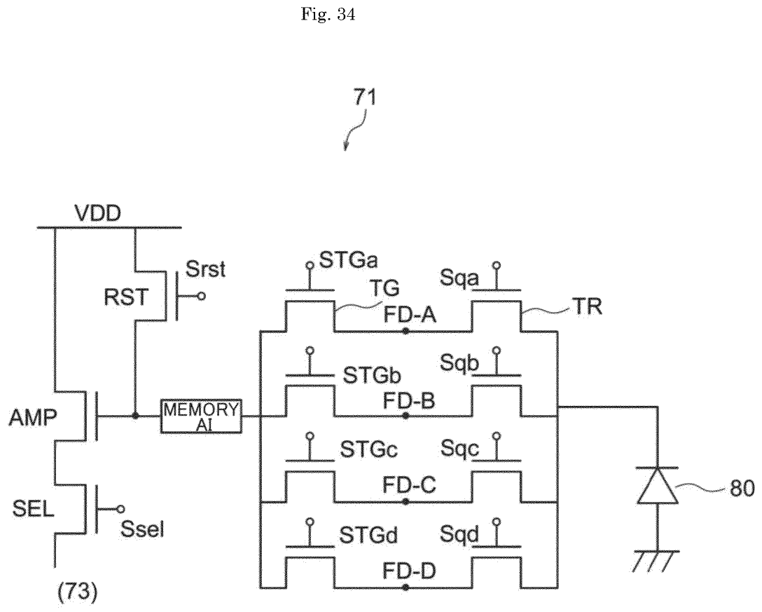

FIG. 34 is a diagram illustrating an equivalent circuit example of the pixel 71 according to the seventh embodiment. One ends of transfer transistors TR are connected to the photoelectric conversion unit 80, and the other ends are connected to the first charge accumulation region FD-A, the second charge accumulation region FD-B, the third charge accumulation region FD-C, and the fourth charge accumulation region FD-D, respectively.

One ends of gate transistors TG are connected to the first charge accumulation region FD-A, the second charge accumulation region FD-B, the third charge accumulation region FD-C, and the fourth charge accumulation region FD-D, respectively, and the other ends are connected to a memory Al. The memory Al is made from, for example, a meteal oxide semiconductor (MOS). Alternatively, the memory Al is made from, for example, a meteal-insulator-metal (MIM).

For example, the memory Al is disposed on the second floor of the substrate 82c, and each transistor is disposed on the first floor. This allows the memory Al and others to be designed without being restricted by the pixels 71. In this way, the circuit of the pixel 71 can be disposed on the substrate 82 and the substrate 82c that are bonded together.

As in the first embodiment, the amplifier transistor AMP has one end connected to the voltage source VDD and the other end connected to the vertical signal line 73 via the selection transistor SEL. The selection transistor SEL is connected between the source electrode of the amplifier transistor AMP and the vertical signal line 73. When a control signal Ssel supplied to the gate electrode from the row scanning circuit 62 is at high level, the selection transistor SEL enters a conductive state, and outputs a detection signal output from the amplifier transistor AMP to the vertical signal line 73, accordingly.

When a control signal Srst supplied to the gate electrode from the row scanning circuit 62 is at high level, the reset transistor RST enters a conductive state to reset the memory Al. At this time, the row scanning circuit 62 supplies a high-level signal to each gate transistor TG to discharge the accumulated charges in the first charge accumulation region FD-A, the second charge accumulation region FD-B, the third charge accumulation region FD-C, and the fourth charge accumulation region FD-D to reset.

As illustrated in FIG. 20, control signals Sqa, Sqb, Sqc, and Sqd are supplied to the gates of the transfer transistors, respectively, from the row scanning circuit 62. Thus, when the control signals Sqa, Sqb, Sqc, and Sqd are at high level, electric charges are accumulated in the first charge accumulation region FD-A, the second charge accumulation region FD-B, the third charge accumulation region FD-C, and the fourth charge accumulation region FD-D, respectively.

Then, after the measurement is completed, the row scanning circuit 62 again sets the reset transistor RST to high level to discharge the accumulated charges in the memory Al to reset. Subsequently, a control signal STGa is set to high level to transfer the electric charges in the first charge accumulation region FD-A to the memory Al, and a detection signal is output to the vertical signal line 73 via the amplifier transistor AMP.

Similarly, the row scanning circuit 62 again sets the reset transistor RST to high level to discharge the accumulated charges in the memory Al to reset. Subsequently, a control signal STGb is set to high level to transfer the electric charges in the second charge accumulation region FD-B to the memory Al, and a detection signal is output to the vertical signal line 73 via the amplifier transistor AMP. Repeating such an operation makes it possible to read out the accumulated charges in each of the first charge accumulation region FD-A, the second charge accumulation region FD-B, the third charge accumulation region FD-C, and the fourth charge accumulation region FD-D as a detection signal. As can be seen from these, it is possible to share the reset transistor RS, the amplifier transistor AMP, and the selection transistor SEL. This makes it possible to eliminate amplifier gain errors compared to the case where an amplifier is configured for each of the first charge accumulation region FD-A, the second charge accumulation region FD-B, the third charge accumulation region FD-C, and the fourth charge accumulation region FD-D. Therefore, the distance measurement error σdepth (see Expression (1)) can be further suppressed.

### Eighth Embodiment

A distance measuring device 10 according to a ninth embodiment differs from the distance measuring device 10 according to the first embodiment in that the shapes of the fifth conductor DTIC-0, the sixth conductor DTIC-1, the seventh conductor DTIC-2, and the eighth conductor DTIC-3 are arranged to conform to the collected shape of the reflected light. Differences from the distance measuring device 10 according to Modification Example 1 of the first embodiment will be described below.

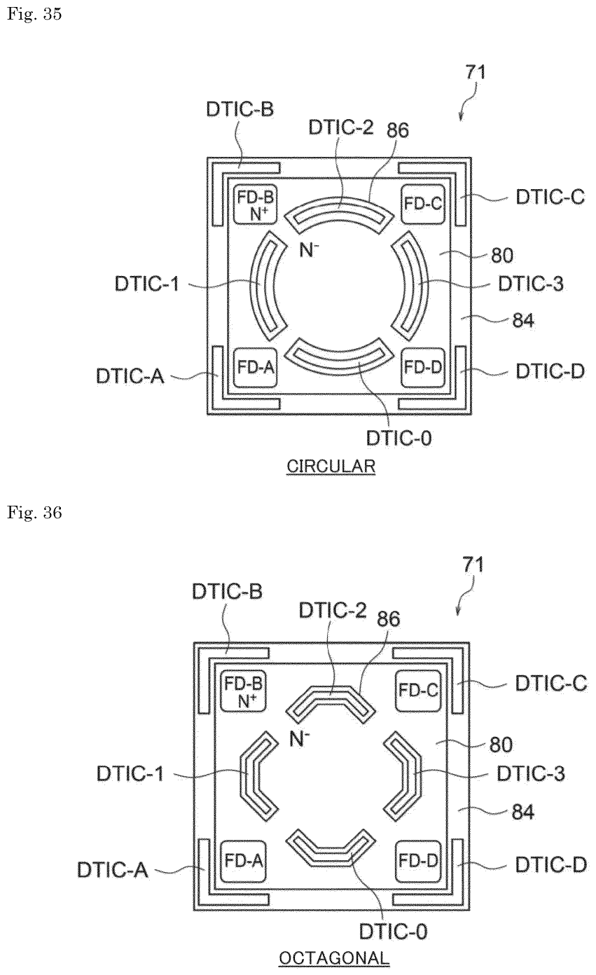

FIG. 35 is a plan view illustrating a configuration example of a pixel 71 according to an eighth embodiment. As illustrated in FIG. 35, the shapes of the fifth conductor DTIC-0, the sixth conductor DTIC-1, the seventh conductor DTIC-2, and the eighth conductor DTIC-3 are arranged in a circular shape to conform to the collected shape of the reflected light. As a result, the shape of the electric potential formed from the center of the photoelectric conversion unit 80 approaches point symmetry and overlaps with the electron generation distribution, making it possible to increase the transfer efficiency of electrons to the first charge accumulation region FD-A, the second charge accumulation region FD-B, the third charge accumulation region FD-C, and the fourth charge accumulation region FD-D. Thus, even when the drive frequency Fmod is further increased, a decrease in the electric charge distribution efficiency Cmod (see Expression 1) is further suppressed.

### Modification Example 1 of Eighth Embodiment

A distance measuring device 10 according to Modification Example 1 of the eighth embodiment differs from the distance measuring device 10 according to the eighth embodiment in that the shapes of the fifth conductor DTIC-0, the sixth conductor DTIC-1, the seventh conductor DTIC-2, and the eighth conductor DTIC-3 are arranged in an octagonal shape. Differences from the distance measuring device 10 according to Modification Example 1 of the first embodiment will be described below.

FIG. 36 is a plan view illustrating a configuration example of a pixel 71 according to Modification Example 1 of the eighth embodiment. As illustrated in FIG. 36, the shapes of the fifth conductor DTIC-0, the sixth conductor DTIC-1, the seventh conductor DTIC-2, and the eighth conductor DTIC-3 are arranged in an octagonal shape to conform to the collected shape of the reflected light. As a result, the shape of the electric potential formed from the center of the photoelectric conversion unit 80 approaches point symmetry and overlaps with the electron generation distribution, so that the transfer efficiency of electrons to the first charge accumulation region FD-A, the second charge accumulation region FD-B, the third charge accumulation region FD-C, and the fourth charge accumulation region FD-D is increased. Thus, even when the drive frequency Fmod is further increased, a decrease in the electric charge distribution efficiency Cmod (see Expression 1) is further suppressed. Furthermore, the fifth conductor DTIC-0, the sixth conductor DTIC-1, the seventh conductor DTIC-2, and the eighth conductor DTIC-3 can be arranged in linear shapes, and therefore, manufacturing becomes easier.

### Ninth Embodiment

A distance measuring device 10 according to a ninth embodiment differs from the distance measuring device 10 according to the first embodiment in that the first conductor DTIC-A, the second conductor DTIC-B, the third conductor DTIC-C, and the fourth conductor DTIC-D are each shared by adjacent pixels. Differences from the distance measuring device 10 according to the first embodiment will be described below.

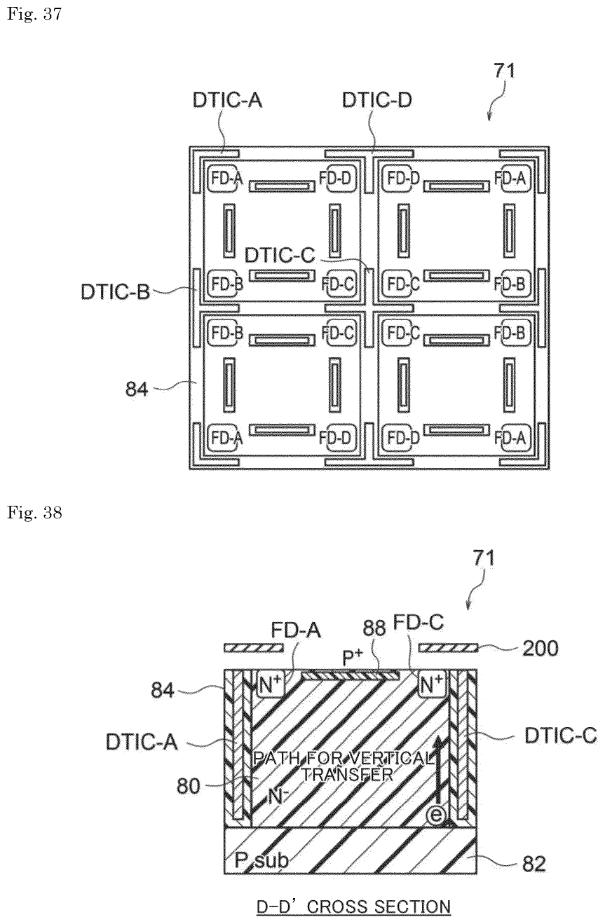

FIG. 37 is a plan view illustrating a configuration example of a pixel 71 according to the ninth embodiment. As illustrated in FIG. 37, the distance measuring device 10 according to the ninth embodiment provides the first conductor DTIC-A, the second conductor DTIC-B, the third conductor DTIC-C, and the fourth conductor DTIC-D for adjacent pixels. This allows the first insulator 84 to be made thinner, so that the pitch of the pixels 71 can be further reduced, and the resolution of the distance measuring device 10 can be increased.

### Tenth Embodiment

A distance measuring device 10 according to a tenth embodiment differs from the distance measuring device 10 according to the first embodiment in that a reflective material 200 is disposed above each of the first conductor DTIC-A, the second conductor DTIC-B, the third conductor DTIC-C, and the fourth conductor DTIC-D. Differences from the distance measuring device 10 according to the first embodiment will be described below.

FIG. 38 is a cross-sectional view taken along AA (see FIG. 5) illustrating a configuration example of a pixel 71 according to the tenth embodiment. As illustrated in FIG. 38, the reflective material 200 is disposed above each of the first conductor DTIC-A, the second conductor DTIC-B, the third conductor DTIC-C, and the fourth conductor DTIC-D. The reflective material 200 is a metal material with high reflectivity, such as tungsten or aluminum. In this way, a light-shielding structure is provided by the reflective material 200 directly above a path through which electric charges are vertically transferred. This makes it possible to suppress the parasitic light sensitivity (PLS) component.

### Eleventh Embodiment

A distance measuring device 10 according to an eleventh embodiment differs from the distance measuring device 10 according to Modification Example 1 of the second embodiment in that a reflective material 200 is disposed above each of the first conductor DTIC-A, the second conductor DTIC-B, the third conductor DTIC-C, and the fourth conductor DTIC-D. Differences from the distance measuring device 10 according to Modification Example 1 of the second embodiment will be described below.

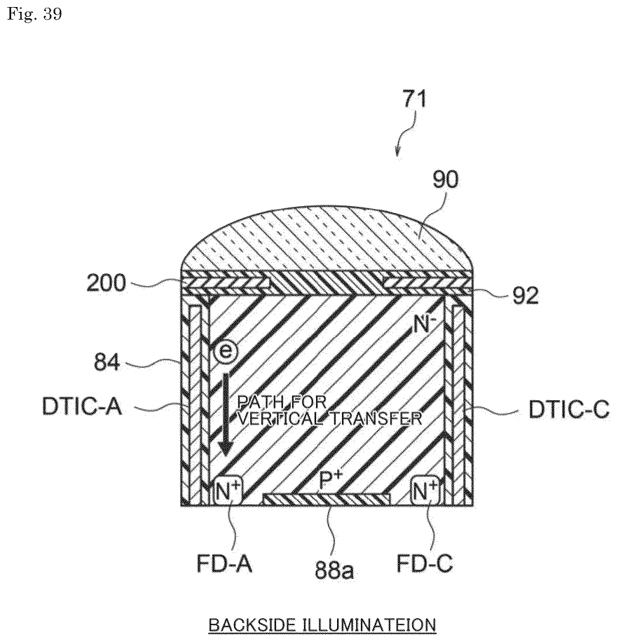

FIG. 39 is a cross-sectional view taken along AA (see FIG. 21) illustrating a configuration example of a pixel 71 according to the eleventh embodiment. As illustrated in FIG. 39, a reflective material 200 is disposed inside an insulating film 92 having a P-type impurity. The reflective material 200 is a metal material with high reflectivity, such as tungsten or aluminum. In this way, a light-shielding structure is provided by the reflective material 200 directly above a path through which electric charges are vertically transferred. This makes it possible to suppress the PLS component even in the case of backside illumination.

### Twelfth Embodiment

A distance measuring device 10 according to a twelfth embodiment differs from the distance measuring device 10 according to the first embodiment in that the fifth conductor DTICR-0, the sixth conductor DTICR-1, the seventh conductor DTICR-2, and the eighth conductor DTICR-3 are made of a material with high reflectivity. Differences from the distance measuring device 10 according to Modification Example 1 of the first embodiment will be described below.

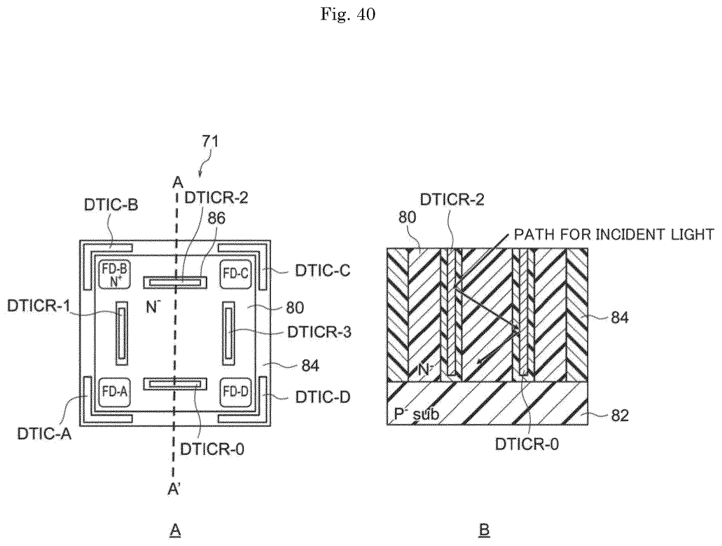

FIG. 40 is a diagram illustrating a configuration example of a pixel 71 according to the twelfth embodiment. Figure A is a plan view, and Figure B is a cross-sectional view taken along AA. As illustrated in FIG. 40, the fifth conductor DTICR-0, the sixth conductor DTICR-1, the seventh conductor DTICR-2, and the eighth conductor DTICR-3 are made of a material with high reflectivity. The fifth conductor DTICR-0, the sixth conductor DTICR-1, the seventh conductor DTICR-2, and the eighth conductor DTICR-3 are made of a metal material having high reflectivity, such as tungsten or aluminum. As a result, as illustrated in Figure B, light is reflected within the photoelectric conversion unit 80, improving the electric charge generation rate. This improves the so-called Qe.

### Thirteenth Embodiment

A distance measuring device 10 according to a thirteenth embodiment differs from the distance measuring device 10 according to the first embodiment in that the reset transistor RS, the amplifier transistor AMP, and the selection transistor SEL are arranged in the photoelectric conversion unit 80. Differences from the distance measuring device 10 according to Modification Example 1 of the first embodiment will be described below.

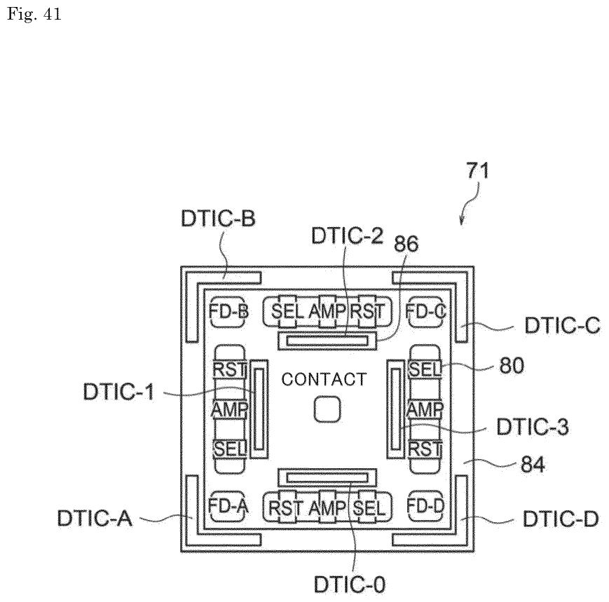

FIG. 41 is a plan view illustrating a configuration example of a pixel 71 according to the thirteenth embodiment. As illustrated in FIG. 41, the reset transistor RS, the amplifier transistor AMP, and the selection transistor SEL (see FIGS. 13 to 18) are arranged in the photoelectric conversion unit 80. This allows the amount of wiring on the substrate 82 side to be reduced.

The present technology can have the following configurations.

(1)

A light receiving element including a plurality of pixels, each pixel including
a photoelectric conversion unit that generates carriers according to an amount of received light;
a first conductor portion that is disposed inside a first insulator that provides insulation between adjacent pixels;
a second conductor portion that is disposed on an outer edge side of a light receiving region of the photoelectric conversion unit and has an opening region; and
a charge accumulation region that corresponds to the opening region and is disposed further on an outer edge side than the second conductor portion.
   (2)

The light receiving element according to (1), wherein
the photoelectric conversion unit is made of a semiconductor of a first conductivity type, and
the charge accumulation region is disposed on one surface side of the photoelectric conversion unit, and has a higher impurity density than the photoelectric conversion unit.
   (3)

The light receiving element according to (1), wherein the second conductor portion is disposed inside a second insulator that provides insulation from the photoelectric conversion unit.

(4)

The light receiving element according to (3), wherein the second conductor portion includes first, second, third, and fourth conductors that are spaced apart from one another.

(5)

The light receiving element according to (4), wherein the first, second, third, and fourth conductors are arranged to surround the light receiving region of the photoelectric conversion unit.

(6)

The light receiving element according to (4), wherein the first, second, third, and fourth conductors are each arranged in any one of a quadrangular shape, a circular shape, and an octagonal shape.

(7)

The light receiving element according to (6), wherein the second insulator is disposed for each of the first, second, third, and fourth conductors so that resulting second insulators are spaced apart from one another.

(8)

The light receiving element according to (6), wherein each of the first, second, third, and fourth conductors is made up of two conductors spaced apart from each other.

(6)

The light receiving element according to (8), wherein
each of the first, second, third, and fourth conductors is made up of two conductors spaced apart from each other, and
second insulators in which the two spaced-apart conductors are arranged in each second insulator are arranged spaced apart from each other.
   (10)

The light receiving element according to (6), wherein the first conductor portion and the second conductor portion run from one surface side to the other surface side of the photoelectric conversion unit.

(11)

The light receiving element according to (4), wherein the charge accumulation region includes first, second, third, and fourth charge accumulation regions that are arranged spaced apart from one another.

(12)

The light receiving element according to (9), wherein
the charge accumulation region includes first to eighth charge accumulation regions that are spaced apart from one another, and
the first to eighth charge accumulation regions are arranged corresponding to eight opening regions of the second conductor portion, respectively.
   (13)

The light receiving element according to (1), further including, in a center of the photoelectric conversion unit, a central conductor portion that is surrounded by an insulator that provides insulation from the photoelectric conversion unit, wherein
a predetermined electric potential is applied to the central conductor portion.
   (14)

The light receiving element according to (2), wherein an on-chip lens is disposed on the other surface side of the photoelectric conversion unit.

(15)

The light receiving element according to (2), wherein an impurity layer of a second conductivity type different from the first conductivity type is disposed in a surface layer of the photoelectric conversion unit.

(16)

The light receiving element according to (15), wherein the impurity layer has a fixed electric potential.

(17)

The light receiving element according to (11), wherein
the first conductor portion includes conductors that are spaced apart from one another corresponding to the first, second, third, and fourth charge accumulation regions, and are applied with a predetermined electric potential,
first, second, third, and fourth periodic signals whose electric potential changes periodically are applied to the first, second, third, and fourth conductors, respectively, and
phases of the first, second, third, and fourth periodic signals differ from one another by 90 degrees.
   (18)

The light receiving element according to (12), wherein
the first conductor portion includes conductors that are spaced apart from one another corresponding to the first to eighth charge accumulation regions, and are applied with a predetermined electric potential,
first to eighth periodic signals whose electric potential changes periodically are applied to the eight spaced-apart conductors, respectively, and
phases of the first to eighth periodic signals differ from one another by 45 degrees.
   (19)

The light receiving element according to (12), wherein
the first to eighth charge accumulation regions have pairs of charge accumulation regions with respect to the center of the photoelectric conversion unit,
the first conductor portion includes conductors that are spaced apart from one another corresponding to the first to eighth charge accumulation regions, and are applied with a predetermined electric potential,
four groups, each being made up of four conductors that form two openings corresponding to the pair of charge accumulation regions, are made,
first to fourth periodic signals whose electric potential changes periodically are applied to the four conductors in each of the four groups, and
phases of the first to fourth periodic signals differ from one another by 90 degrees.
   (20)

The light receiving element according to (11), further including a substrate that is disposed on one surface side of the photoelectric conversion unit, wherein the first, second, third, and fourth charge accumulation regions are arranged on the substrate,
the first conductor portion includes first, second, third, and fourth first conductors that are separated apart from one another corresponding to the first, second, third, and fourth charge accumulation regions, and
each of the first, second, third, and fourth charge accumulation regions is connected to a corresponding one of the first, second, third, and fourth first conductors via a gate transistor.
   (21)

The light receiving element according to (11), further including a substrate that is disposed on one surface side of the photoelectric conversion unit, wherein
the first, second, third, and fourth charge accumulation regions are arranged on the substrate,
the first conductor portion includes first, second, third, and fourth first conductors that are separated apart from one another corresponding to the first, second, third, and fourth charge accumulation regions,
the light receiving element further includes a first, second, third, and fourth embedded memories adjacent to the first, second, third, and fourth first conductors, respectively, and
each of the first, second, third, and fourth charge accumulation regions is connected to a corresponding one of the first, second, third, and fourth embedded memories via a gate transistor.
   (22)

The light receiving element according to (21), wherein the first insulator and the second insulator are integrally formed to electrically isolate the first, second, third, and fourth embedded memories.

(23)

The light receiving element according to (11), further including:
a substrate disposed on one surface side of the photoelectric conversion unit; and
a memory electrically connectable to the first, second, third, and fourth charge accumulation regions, wherein
the memory is formed in the substrate.
   (24)

The light receiving element according to (23), wherein the memory is formed of meteal oxide semiconductor (MOS) or meteal-insulator-metal (MIM).

(25)

The light receiving element according to (1), wherein the first conductor portion is shared between adjacent pixels.

(26)

The light receiving element according to (11), wherein
the first conductor portion includes conductors that are spaced apart from one another corresponding to the first, second, third, and fourth charge accumulation regions, and
the light receiving element further includes a light-shielding portion that covers one side or the other side of the spaced-apart first conductor portion.
   (27)

The light receiving element according to (4), wherein the first, second, third, and fourth conductors are made of a metal material having a predetermined reflectivity.

(28)

The light receiving element according to (11), wherein circuits configured corresponding to the first, second, third, and fourth charge accumulation regions are arranged in the photoelectric conversion unit.

(29)

A distance measuring device including:
the light receiving element according to (1); and
a signal processing unit that generates a distance measurement value to a target object using a measurement signal based on the light receiving element.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

### REFERENCE SIGNS LIST

10 Distance measuring device
42 Light receiving element
43 Signal processing unit
71 Pixel
80 Photoelectric conversion unit
82 Substrate
84 First insulator
86 Second insulator
90 On-chip lens
Al Memory
DTIC-A to DTIC-D First to fourth conductors
DTIC-0 to DTIC-3 Fifth to eighth conductors
DTIC-M Conductor (central conductor portion)
DTICa-0 to DTICa-3 Ninth conductor, eleventh conductor, thirteenth conductor,
fifteenth conductor
DTICb-0 to DTICb-3 Tenth conductor, twelfth conductor, fourteenth conductor,
sixteenth conductor
FD-A to FD-D Charge storage region
TG Gate transistor

1. A light receiving element comprising a plurality of pixels,
each pixel including
a photoelectric conversion unit that generates carriers according to an amount of received light;
a first conductor portion that is disposed inside a first insulator that provides insulation between adjacent pixels;
a second conductor portion that is disposed on an outer edge side of a light receiving region of the photoelectric conversion unit and has an opening region; and
a charge accumulation region that corresponds to the opening region and is disposed further on an outer edge side than the second conductor portion.

2. The light receiving element according to claim 1, wherein
the photoelectric conversion unit is made of a semiconductor of a first conductivity type, and
the charge accumulation region is disposed on one surface side of the photoelectric conversion unit, and has a higher impurity density than the photoelectric conversion unit.

3. The light receiving element according to claim 1, wherein the second conductor portion is disposed inside a second insulator that provides insulation from the photoelectric conversion unit.

4. The light receiving element according to claim 3, wherein the second conductor portion includes first, second, third, and fourth conductors that are spaced apart from one another.

5. The light receiving element according to claim 4, wherein the first, second, third, and fourth conductors are arranged to surround the light receiving region of the photoelectric conversion unit.

6. The light receiving element according to claim 4, wherein the first, second, third, and fourth conductors are each arranged in any one of a quadrangular shape, a circular shape, and an octagonal shape.

7. The light receiving element according to claim 6, wherein the second insulator is disposed for each of the first, second, third, and fourth conductors so that resulting second insulators are spaced apart from one another.

8. The light receiving element according to claim 6, wherein each of the first, second, third, and fourth conductors is made up of two conductors spaced apart from each other.

9. The light receiving element according to claim 8, wherein
each of the first, second, third, and fourth conductors is made up of two conductors spaced apart from each other, and
second insulators in which the two spaced-apart conductors are arranged in each second insulator are arranged spaced apart from each other.

10. The light receiving element according to claim 6, wherein the first conductor portion and the second conductor portion run from one surface side to the other surface side of the photoelectric conversion unit.

11. The light receiving element according to claim 4, wherein the charge accumulation region includes first, second, third, and fourth charge accumulation regions that are arranged spaced apart from one another.

12. The light receiving element according to claim 9, wherein
the charge accumulation region includes first to eighth charge accumulation regions that are spaced apart from one another, and
the first to eighth charge accumulation regions are arranged corresponding to eight opening regions of the second conductor portion, respectively.

13. The light receiving element according to claim 1, further comprising, in a center of the photoelectric conversion unit, a central conductor portion that is surrounded by an insulator that provides insulation from the photoelectric conversion unit, wherein
a predetermined electric potential is applied to the central conductor portion.

14. The light receiving element according to claim 2, wherein an on-chip lens is disposed on the other surface side of the photoelectric conversion unit.

15. The light receiving element according to claim 2, wherein an impurity layer of a second conductivity type different from the first conductivity type is disposed in a surface layer of the photoelectric conversion unit.

16. The light receiving element according to claim 15, wherein the impurity layer has a fixed electric potential.

17. The light receiving element according to claim 11, wherein
the first conductor portion includes conductors that are spaced apart from one another corresponding to the first, second, third, and fourth charge accumulation regions, and are applied with a predetermined electric potential,
first, second, third, and fourth periodic signals whose electric potential changes periodically are applied to the first, second, third, and fourth conductors, respectively, and
phases of the first, second, third, and fourth periodic signals differ from one another by 90 degrees.

18. The light receiving element according to claim 12, wherein
the first conductor portion includes conductors that are spaced apart from one another corresponding to the first to eighth charge accumulation regions, and are applied with a predetermined electric potential,
first to eighth periodic signals whose electric potential changes periodically are applied to the eight spaced-apart conductors, respectively, and
phases of the first to eighth periodic signals differ from one another by 45 degrees.

19. The light receiving element according to claim 12, wherein
the first to eighth charge accumulation regions have pairs of charge accumulation regions with respect to the center of the photoelectric conversion unit,
the first conductor portion includes conductors that are spaced apart from one another corresponding to the first to eighth charge accumulation regions, and are applied with a predetermined electric potential,
four groups, each being made up of four conductors that form two openings corresponding to the pair of charge accumulation regions, are made,
first to fourth periodic signals whose electric potential changes periodically are applied to the four conductors in each of the four groups, and
phases of the first to fourth periodic signals differ from one another by 90 degrees.

20. The light receiving element according to claim 11, further comprising a substrate that is disposed on one surface side of the photoelectric conversion unit, wherein the first, second, third, and fourth charge accumulation regions are arranged on the substrate,
the first conductor portion includes first, second, third, and fourth first conductors that are separated apart from one another corresponding to the first, second, third, and fourth charge accumulation regions, and
each of the first, second, third, and fourth charge accumulation regions is connected to a corresponding one of the first, second, third, and fourth first conductors via a gate transistor.

21. The light receiving element according to claim 11, further comprising a substrate that is disposed on one surface side of the photoelectric conversion unit, wherein the first, second, third, and fourth charge accumulation regions are arranged on the substrate,
the first conductor portion includes first, second, third, and fourth first conductors that are separated apart from one another corresponding to the first, second, third, and fourth charge accumulation regions,
the light receiving element further comprises a first, second, third, and fourth embedded memories adjacent to the first, second, third, and fourth first conductors, respectively, and
each of the first, second, third, and fourth charge accumulation regions is connected to a corresponding one of the first, second, third, and fourth embedded memories via a gate transistor.

22. The light receiving element according to claim 21, wherein the first insulator and the second insulator are integrally formed to electrically isolate the first, second, third, and fourth embedded memories.

23. The light receiving element according to claim 11, further comprising:
a substrate disposed on one surface side of the photoelectric conversion unit; and
a memory electrically connectable to the first, second, third, and fourth charge accumulation regions, wherein
the memory is formed in the substrate.

24. The light receiving element according to claim 23, wherein the memory is formed of meteal oxide semiDTICuctor (MOS) or meteal-insulator-metal (MIM).

25. The light receiving element according to claim 1, wherein the first conductor portion is shared between adjacent pixels.

26. The light receiving element according to claim 11, wherein
the first conductor portion includes conductors that are spaced apart from one another corresponding to the first, second, third, and fourth charge accumulation regions, and
the light receiving element further comprises a light-shielding portion that covers one side or the other side of the spaced-apart first conductor portion.

27. The light receiving element according to claim 4, wherein the first, second, third, and fourth conductors are made of a metal material having a predetermined reflectivity.

28. The light receiving element according to claim 11, wherein circuits configured corresponding to the first, second, third, and fourth charge accumulation regions are arranged in the photoelectric conversion unit.

29. A distance measuring device comprising:
the light receiving element according to claim 1; and
a signal processing unit that generates a distance measurement value to a target object using a measurement signal based on the light receiving element.
